(19) United States
(12) Patent Application Publication
(10) Pub. No.: US 2026/0120741 A1
(43) Pub. Date: Apr. 30, 2026

(54) CHARGE-DOMAIN COMPUTE-IN-MEMORY USING FERROELECTRIC FIELD-EFFECT TRANSISTOR NAND ARCHITECTURES

(71) Applicants: University of Notre Dame du Lac, South Bend, IN (US); The Penn State Research Foundation, University Park, NJ (US)

(72) Inventors: Kai Ni, Notre Dame, IN (US); Siddharth Joshi, Notre Dame, IN (US); Vijaykrishnan Narayanan, State College, PA (US)

(21) Appl. No.: 19/372,803

(22) Filed: Oct. 29, 2025

Related U.S. Application Data
(60) Provisional application No. 63/713,365, filed on Oct. 29, 2024.

(51) Int. Cl. G11C 11/22; G06F 7/544

(52) U.S. Cl. CPC G11C 11/2273; G06F 7/5443; G11C 11/221; G11C 11/2275

(57) ABSTRACT

Disclosed are compute-in-memory devices that perform charge-domain MAC operations in a NAND-style string of FeFETs. Memory cells are coupled to word lines and bit lines, each FeFET storing a computational weight as a non-volatile polarization state established by polarization switching of a ferroelectric layer, the polarization state altering channel conduction and modulating gate capacitance. A selected read cell receives an input signal on a bit line, and a neighboring memory cell provides a sense node at its word line formed by the neighboring cell's gate capacitance. A control circuit biases the read and neighboring cells so that application of the input signal to the read cell conditionally transfers charge to the neighboring cell's gate capacitance according to the combination of the input and the read cell's polarization-dependent conduction state. A readout circuit senses an electrical quantity to yield a MAC compute result in the charge domain.

### RELATED APPLICATIONS

This application claims the benefit of priority under 35 U.S.C. § 119 (e) to U.S. Provisional Patent Application No. 63/713,365, filed Oct. 29, 2024, entitled “CHARGE-DOMAIN COMPUTE-IN-MEMORY ARCHITECTURE USING VERTICAL NAND FERROELECTRIC FETS,” which is incorporated herein by reference. Any and all applications for which a foreign or domestic priority claim is identified in the Application Data Sheet as filed with the present application are incorporated by reference under 37 CFR 1.57 and made a part of this specification.

### STATEMENT OF GOVERNMENT SUPPORT

This invention was made with government support under award HR0011-23-3-0002 awarded by the Defense Advanced Research Projects Agency (DARPA) and grants CCF2344819, 2235366, 2235472 and CCF2340799 awarded by the National Science Foundation (NSF). The government has certain rights in the invention.

### FIELD

The present disclosure relates to compute-in-memory architectures and, more particularly, to memory devices and circuits that perform computational operations within non-volatile memory arrays.

### BACKGROUND

The rapid growth of artificial intelligence (AI) and machine learning (ML) has led to increasingly large and complex neural network models. These models often contain billions of parameters and require substantial computational resources to perform multiply-accumulate (MAC) operations during inference and training. Traditional von Neumann computing architectures rely on frequent data transfer between separate memory and processing units, causing latency, high power consumption, and limited scalability.

Conventional memory technologies such as dynamic random-access memory (DRAM) and static random-access memory (SRAM) face challenges in meeting the demands of modern neural network workloads due to bandwidth limitations, leakage power, and poor energy efficiency. To address these limitations, compute-in-memory (CIM) architectures have emerged, in which computation is performed directly within memory arrays to reduce data movement.

Many existing CIM designs utilize current-domain computation, where MAC operations are performed by summing currents through memory cells. However, current-domain approaches become less efficient as array sizes increase, because current summation across long strings or large arrays introduces significant variability, noise, and power consumption. Furthermore, process variations in memory devices can degrade accuracy and reliability in current-domain CIM.

Some non-volatile memory technologies, such as resistive RAM (ReRAM), phase-change memory (PCM), magnetoresistive RAM (MRAM), and ferroelectric field-effect transistors (FeFETs), offer promising characteristics for CIM implementations, including low leakage, scalability, and analog or multi-level capability. Among these technologies, NAND-based memory structures provide high density and mature fabrication processes. However, integrating CIM functionality into NAND structures presents challenges due to device string architecture, parasitic effects, and limited accessibility of internal nodes.

### SUMMARY

A compute-in-memory device can include a plurality of memory cells arranged in a string and coupled to a plurality of word lines and bit lines. Each memory cell can be a FeFET that stores data as a polarization state of a ferroelectric layer. The polarization state can modify a conduction characteristic and a gate capacitance of the memory cell.

In some embodiments, the device can include a read cell selected from the plurality of memory cells and a neighboring memory cell adjacent to the read cell. A control circuit can apply an input signal to the read cell and bias the neighboring memory cell such that charge is conditionally transferred to the neighboring memory cell's gate capacitance according to a combination of the input signal and the polarization-dependent conduction state of the read cell. A readout circuit can sense an electrical quantity, such as a voltage on a word line of the neighboring memory cell, to obtain a compute result corresponding to a multiply-accumulate operation performed in a charge domain.

In some embodiments, a multiply-accumulate operation can be performed locally without summing current across multiple memory cells in the string. Charge accumulation on the neighboring memory cell's gate capacitance can represent the output of the computation. The control circuit can sequentially select different pairs of adjacent memory cells as the read cell and neighboring memory cell to perform successive charge-domain operations along the string.

In some embodiments, a compute-in-memory device can operate with binary or multi-level input signals and can be fabricated using CMOS-compatible processes. The plurality of memory cells can be vertically stacked in a three-dimensional NAND structure to achieve high density, low power consumption, and scalability for artificial intelligence and machine learning applications . . .

### BRIEF DESCRIPTION OF THE DRAWINGS

Throughout the drawings, reference numbers can be re-used to indicate correspondence between referenced elements. The drawings are provided to illustrate embodiments of the present disclosure and do not to limit the scope thereof.

FIG. 1A illustrates a representative trend showing the exponential increase in the number of parameters used in artificial-intelligence and machine-learning neural-network models over time.

FIG. 1B illustrates the scaling trend of NAND-memory technology density over time.

FIG. 1C illustrates an example three-dimensional NAND memory structure that can be implemented to perform charge-domain compute-in-memory operations, in accordance with some aspects of the inventive concepts.

FIG. 1D presents a comparative summary of different NAND-array-based CIM architectures, referencing prior works and some aspects of the inventive concepts disclosed herein.

FIGS. 2A-2C illustrate example operation principles for a charge-domain CIM architecture that can employ FeFETs arranged in NAND-type strings.

FIGS. 3A-3E illustrate an example process flow and characterization results for a FeFET device that can be used within a NAND string or compute-in-memory array.

FIGS. 4A-4C illustrate example electrical characterization results of the fabricated FeFET.

FIGS. 5A-5E illustrate the retention and endurance characteristics of the fabricated FeFET.

FIGS. 6A-6H illustrate example validation of charge-domain Fe-NAND CIM operation using a fabricated two-FeFET NAND string integrated with a read transistor.

FIGS. 7A-7B illustrate the structure and programming methodology of an integrated 2×2 Fe-NAND array fabricated to validate charge-domain MAC operation.

FIG. 7C shows the measured drain-current (I_{D}) versus gate-voltage (V_{G}) characteristics for multiple FeFET devices after initialization and programming without inhibition.

FIG. 7D presents corresponding I_{D}-V_{G} characteristics obtained from the same array when programming is performed with inhibition applied according to the biasing scheme described in FIG. 7B.

FIG. 7E illustrates the operational principle of the MAC function performed within the fabricated 2×2 Fe-NAND array.

FIG. 7F presents the measured read-bit-line current (I_{RBL}) as a function of time for different MAC outputs obtained from the array.

FIG. 7G illustrates the measured read-bit-line current (I_{RBL}) results for different combinations of binary input (X) and binary weight (W) states in the 2×2 Fe-NAND array.

FIG. 7H illustrates an extension of the same Fe-NAND array operation for nonbinary input computation.

FIG. 7I shows the measured read-bit-line current (I_{RBL}) waveforms obtained during nonbinary input operation of the 2×2 Fe-NAND array.

FIG. 7J presents the transfer characteristic (I_{D}-V_{G}) of the integrated read transistor used to convert the sensed charge from the Fe-NAND array into measurable current.

FIG. 7K shows the extracted V_{c,eff} as a function of the MAC output index obtained from the nonbinary computation tests.

FIGS. 8A-8F illustrate simulated characteristics of a charge-domain CIM architecture based on FeFET NAND strings, evaluated using a 28 nm process design kit (PDK).

FIG. 9A presents a schematic diagram of the Fe-NAND subarray design, showing the main circuit components that enable charge-domain computation.

FIG. 9B provides a quantitative comparison between the disclosed Fe-NAND charge-domain CIM system and prior NAND-based CIM works.

### DETAILED DESCRIPTION

### Introduction

Modern compute-in-memory (CIM) schemes implemented on NAND arrays commonly rely on current-domain sensing, in which multiply-accumulate (MAC) operations are realized by summing string currents at the end of a long device chain. Such approaches can be highly sensitive to device-to-device variation across the entire string, suffer from non-ideal linearity, and incur elevated read energy as arrays scale. There is therefore a need for CIM architectures that perform MAC locally, reduce dependence on cumulative string conduction, and natively support multi-level inputs while remaining compatible with high-density NAND integration.

Some inventive concepts disclosed herein relate to a charge-domain CIM architecture that employs a NAND-type array of ferroelectric field-effect transistors (FeFETs). Each memory cell can store a computational weight as a non-volatile ferroelectric polarization state that alters a conduction characteristic and/or modulates the device's gate capacitance. During inference, a read cell receives an input signal on a bit line, and an adjacent, neighboring memory cell provides a sense node at its word line (WL). A control circuit biases the pair so that the applied input conditionally transfers charge from the read cell to the gate capacitance of the neighboring cell, producing a charge proportional to the product of the input and the stored weight. In this manner, MAC is performed in the charge domain without summing currents through the entire string.

In some implementations, the control circuit turns ON cells on one side of the read cell to propagate the bit-line input toward the read cell and turns OFF cells on the opposite side of the neighboring cell to isolate the sense node. Different adjacent pairs can be sequentially selected along the word-line direction to perform successive dot-product operations. The readout circuit senses an electrical quantity at the sense node, e.g., a voltage on the neighboring WL, and may use an optional read transistor to convert accumulated charge into a measurable current. Distinct polarization states establish separated gate-capacitance levels that form a memory window used to differentiate MAC outputs.

Some aspects of the disclosed architecture are compatible with binary and multi-level (analog) input voltages applied on the bit lines. In some cases, the amount of transferred charge scales with input magnitude, enabling graded MAC outputs and facilitating analog-to-digital conversion with simple reference settings. Programming of weights can be carried out with array-level inhibit biasing, in which a program voltage is applied to a target cell while reduced bias is applied to non-selected cells to maintain their polarization states during write, thereby supporting independent weight updates within a string.

By localizing computation to adjacent cell pairs and sensing directly on a neighboring WL, the disclosed charge-domain scheme can improve resilience to device variation, enhance inference accuracy, and reduce power relative to current-domain NAND CIM. The approach remains CMOS- and 3D-NAND-compatible, enabling monolithic integration with peripheral control and readout circuitry (e.g., ADCs) and scalable operation across large arrays.

### Example Three-Dimensional Charge-Domain Compute-in-Memory Architecture

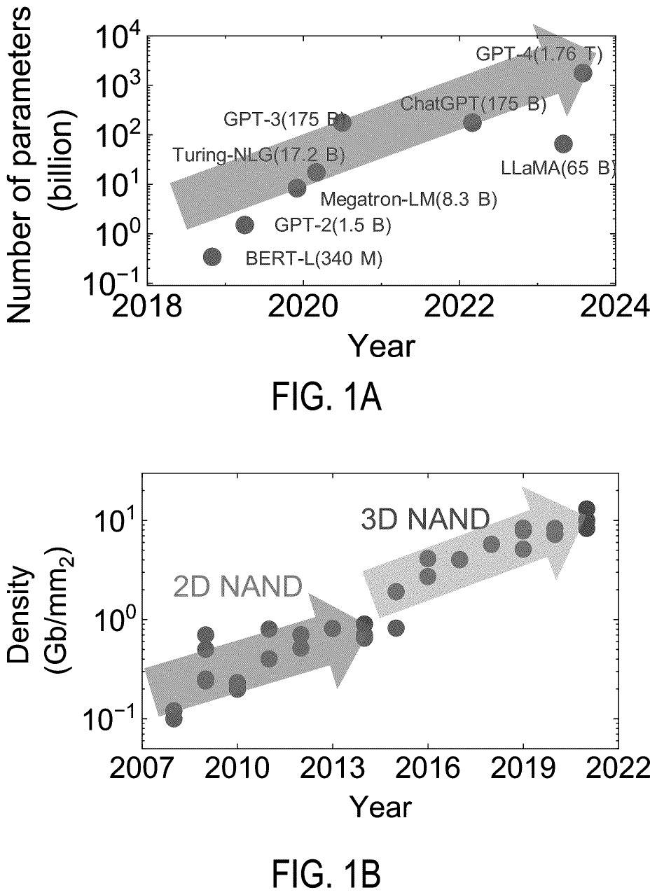

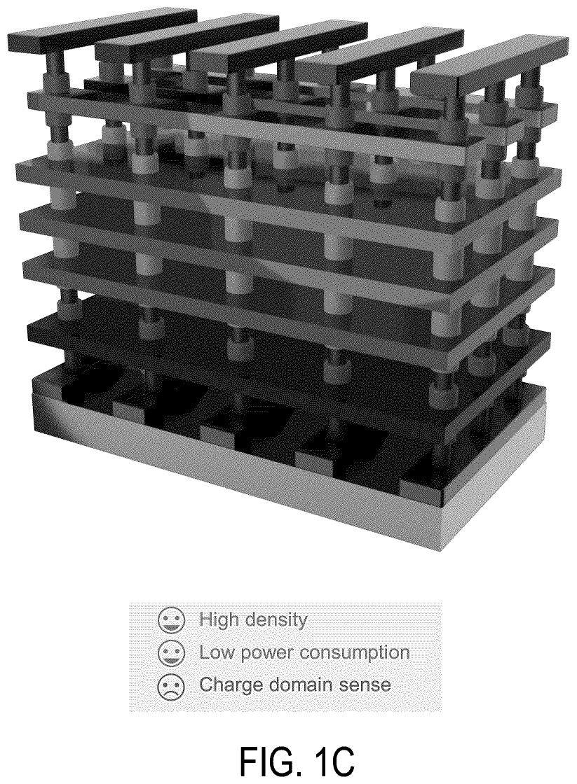

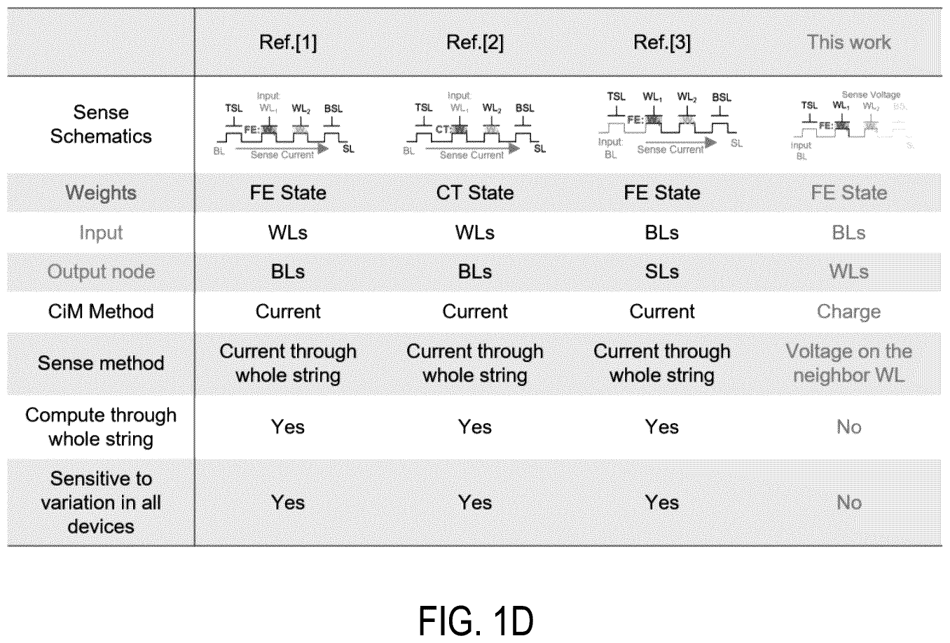

The development of artificial intelligence (AI) and machine learning (ML) has been accompanied by a steady increase in computational requirements. Neural-network (NN) models used in these applications have continued to expand in scale and capability. Over recent years, the number of parameters in such models has increased substantially, with advanced networks now including billions of parameters, as shown in FIG. 1A. Conventional memory technologies such as dynamic random-access memory (DRAM) and static random-access memory (SRAM) are becoming less suited to support these workloads because of constraints in scalability and energy efficiency. Various types of non-volatile memory, including ferroelectric devices, resistive random-access memory (ReRAM), phase-change memory (PCM), and magnetoresistive random-access memory (MRAM), are being investigated as alternatives that may provide reduced energy consumption and data retention without the need for continuous power.

Among these approaches, ferroelectric field-effect transistors (FeFETs) arranged in NAND-based configurations are considered suitable for achieving relatively high density and non-volatile storage, while maintaining general compatibility with NAND fabrication techniques. Many existing NAND architectures for CIM operation are based on current-domain designs, where MAC operations are carried out by summing currents from multiple devices in a string or array at the bottom of the string. Such current-domain implementations may face challenges when scaled to larger arrays and can exhibit sensitivity to device variations, which may affect power use and computational precision. Integrating additional capacitive structures into conventional NAND architectures to support charge-domain CIM operation has also presented certain practical difficulties.

In accordance with some aspects of the inventive concepts, a charge-domain compute-in-memory architecture is described that makes use of the intrinsic gate capacitance of neighboring FeFET cells for charge-domain sensing. This arrangement allows multiplication and accumulation operations to occur locally within the array without the need to sum currents through an entire NAND string. Tests performed on an integrated 2×2 Fe-NAND array that includes a read transistor show that charge-domain computation can be achieved within this configuration. The results also show that the architecture can support both binary and multi-level input operation. A generally linear relationship between the multiply-accumulate output and the effective charge voltage has been observed, suggesting that the approach can be applied to non-binary input computation.

FIG. 1A illustrates a representative trend showing the exponential increase in the number of parameters used in artificial-intelligence and machine-learning neural-network models over time. The horizontal axis represents the year, ranging from approximately 2018 to 2024, and the vertical axis represents the number of parameters in billions on a logarithmic scale. Each plotted point corresponds to a neural-network model used for large-scale computation. The plotted data demonstrate that the number of parameters has grown from hundreds of millions to multiple trillions in a few years, indicating the rapidly escalating computational and storage requirements of modern AI workloads. An upward trend arrow indicates this continuous growth in model size and complexity, underscoring the need for higher-density and lower-power compute-in-memory technologies.

FIG. 1B illustrates the scaling trend of NAND-memory technology density over time. The horizontal axis represents the year, ranging from approximately 2007 to 2022, and the vertical axis represents areal density in gigabits per square millimeter (Gb/mm²) plotted on a logarithmic scale. Data points show two distinct regimes corresponding to two-dimensional (2D) NAND and three-dimensional (3D) NAND structures. The data indicate that density improvements in 2D NAND appear to have reached practical limits around the early 2010s, while 3D NAND continued to scale through layer stacking, achieving substantially greater storage density and reduced cost per bit. The progression from 2D to 3D NAND demonstrates the viability of vertical integration for meeting future high-density and low-power data-storage requirements.

FIG. 1C illustrates an example three-dimensional NAND memory structure that can be implemented to perform charge-domain compute-in-memory operations, in accordance with some aspects of the inventive concepts. FIG. 1C depicts multiple stacked layers of word lines, bit lines, and vertical channel structures forming NAND strings interconnected through a common substrate and peripheral circuitry. Each vertical pillar can include memory elements such as ferroelectric field-effect transistors (FeFETs) arranged in alternating layers with dielectric isolation. The structure can support computation within the memory array by using intrinsic device characteristics such as gate capacitance for charge-domain sensing. This vertically integrated architecture can achieve high storage density, low power consumption, and direct compatibility with complementary metal-oxide-semiconductor (CMOS) fabrication processes, thereby allowing monolithic integration of computation and storage. FIG. 1C represents an example embodiment of the disclosed charge-domain NAND compute-in-memory system.

FIG. 1D presents a comparative summary of different NAND-array-based CIM architectures, referencing prior works [1] (C. Jin et al., IEEE EDL 2023), [2] (L. Zhao et al., IEEE DAC 2021), and [3] (I. Kim et al., Nat Commun 2023) and some aspects of the inventive concepts disclosed herein ([4]). Each column corresponds to a representative design, showing schematic sensing configurations, signal flow, and the type of computational operation performed. The table includes rows identifying the configuration of weights, input nodes, and output nodes, as well as the associated sensing and computation methods. The referenced designs in [1], [2], and [3] implement current-domain CIM, in which sensing is performed by summing currents through the entire NAND string. By contrast, some aspects of the inventive concepts may employ charge-domain computation, in which a voltage is sensed on a neighboring word line rather than measuring string current. The table further indicates that current-domain CIM approaches often require computation through all devices in the string and exhibit sensitivity to device-to-device variation, whereas some inventive concepts disclosed herein relate to charge-domain approaches that perform localized computation and are less affected by variations, thereby offering improved stability and lower energy consumption.

### Operation Principle of Charge-Domain Fe-NAND Compute-in-Memory Architecture

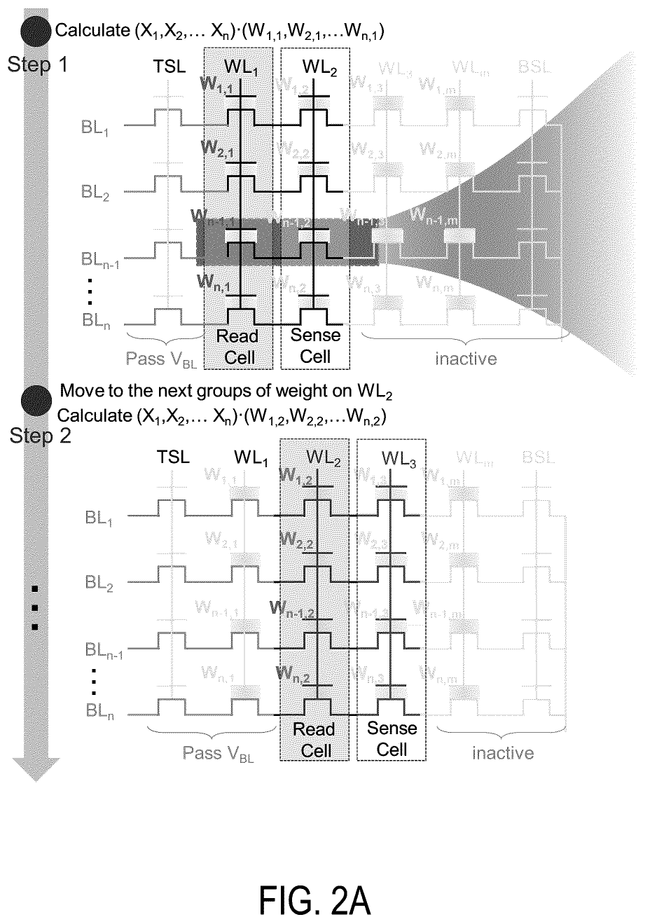

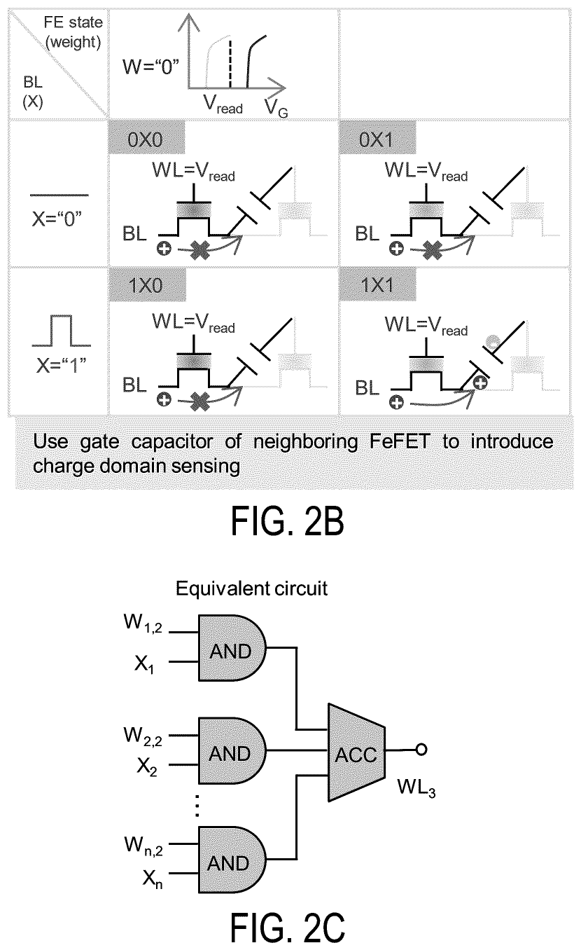

FIGS. 2A-2C illustrate example operation principles for a charge-domain CIM architecture that can employ ferroelectric field-effect transistors (FeFETs) arranged in NAND-type strings. Each memory cell in the array can include a ferroelectric layer capable of storing a non-volatile polarization state. The polarization state can alter a conduction characteristic and can also modulate an effective gate capacitance of the corresponding memory cell, which may represent a computational weight. A plurality of memory cells can be coupled to a plurality of word lines (WLs) and bit lines (BLs) and connected in series within each string between select transistors that can be controlled by a top select line (TSL) and, in some implementations, a bottom select line.

As shown in FIG. 2A, the architecture can perform a MAC operation through conditional charge transfer between adjacent FeFETs. In one example, the computation can be expressed as a dot product between an input vector (X₁, X₂, . . . , Xₙ) and a weight vector (W_{1,1}, W_{2,1}, . . . , W_{n,1}), where each input element Xᵢ can be applied as a voltage on a corresponding bit line (BL) and each weight element W_{i,1} can be stored as a polarization state in an FeFET coupled to a word line (WL₁). During a computation step, the TSL may be biased at a voltage Vₛ₁ to enable conduction through a selected portion of the string. FeFETs coupled to WL₁ can act as read cells, and neighboring FeFETs coupled to WL₂ can serve as sense cells whose word-line nodes form sense nodes. When an input voltage VBL corresponding to X is applied to the bit lines, charge can be conditionally transferred from the channel region of each read cell to the gate capacitance of its corresponding neighboring sense cell.

The conditional charge transfer can depend on both the input voltage and the polarization-dependent conduction state of the read cell. For example, a read cell in a low-threshold-voltage (LVT) state (e.g., polarization “1”) can allow the applied bit-line potential to couple into the sense node when the input X is active (“1”), whereas a high-threshold-voltage (HVT) state (“0”) or an inactive input (“0”) can inhibit charge transfer. This behavior can operate analogously to a logical AND function between the stored weight and the input signal. The accumulated charge on the sense node can correspond to a weighted product (W×X) in the charge domain. Charges across multiple sense nodes can be combined capacitively, thereby realizing a multiply-accumulate function without requiring current summation through the full string.

After one group of weights is processed, the dot product of the same input vector (X₁, X₂, . . . , Xₙ) and the next group of stored weights (W_{1,2}, W_{2,2}, . . . , W_{n,2}) can be computed by activating the next set of word lines (e.g., WL₂) and corresponding sense cells. A control circuit can sequentially activate subsequent groups of word lines (e.g., WL₃, WL₄, and so on) so that each group performs its own localized dot-product computation. During each cycle, cells located on one side of the read cell (for example, those positioned toward the TSL) can be turned ON to propagate the bit-line voltage VBL, while cells located on the opposite side of the neighboring sense cell can be turned OFF to isolate the sense node. This process can continue through successive groups of stored weights until all desired dot-product calculations along the string are completed. The charge accumulated on the gate capacitance of the neighboring FeFET can be retained temporarily or accumulated over multiple input cycles to produce a cumulative MAC result.

As shown in FIG. 2B, a single-cell operation can be represented by four combinations of input and weight states—(0, 0), (0, 1), (1, 0), and (1, 1)—each of which can produce a distinct charge response at the sense node. When both the input X and weight W are “1,” charge can couple through the gate dielectric of the read cell into the gate capacitance of the neighboring sense cell. For the remaining combinations, charge transfer may not occur, and the potential of the sense node can remain substantially unchanged. This conditional charging behavior can result from modulation of the channel potential by the ferroelectric polarization state, which defines the effective gate capacitance and conduction threshold. Accordingly, the gate capacitance of the neighboring FeFET can function as a sensing capacitor that introduces charge-domain computation within the NAND string.

FIG. 2C shows an equivalent-circuit representation for adjacent NAND strings during charge-domain operation. Each input Xᵢ can be combined with its corresponding stored weight W_{i,2} through an effective logical-AND function. The resulting charge components can be accumulated at a sense node or accumulator (ACC) associated with a subsequent word line (WL₃). An equivalent voltage observed at WL₃ can generally follow the proportional relationship:

$${V}_{WL {3}_{α}} {\sum }_{i} {w}_{i , 2} {x}_{i} \qquad ( Equation 1 )$$

which can represent the multiply-accumulate result obtained in the charge domain. A readout circuit coupled to the sense node can convert the accumulated charge into a measurable voltage or current that may be used for further analog-to-digital conversion or inference processing.

In some embodiments, the control circuitry can select different adjacent cell pairs within a string to perform successive MAC operations, allowing serial computation along the word-line direction. The input signals can include binary, multi-level, or analog voltages, such that an amount of transferred charge can scale with the magnitude of the applied input. The polarization states of the FeFETs can define distinct gate-capacitance levels that form a memory window detectable by the readout circuitry. Because computation can occur locally between adjacent cells and may not rely on cumulative current through the entire string, the architecture can exhibit improved energy efficiency and reduced sensitivity to device-to-device variation . . .

### Device Fabrication and Characterization

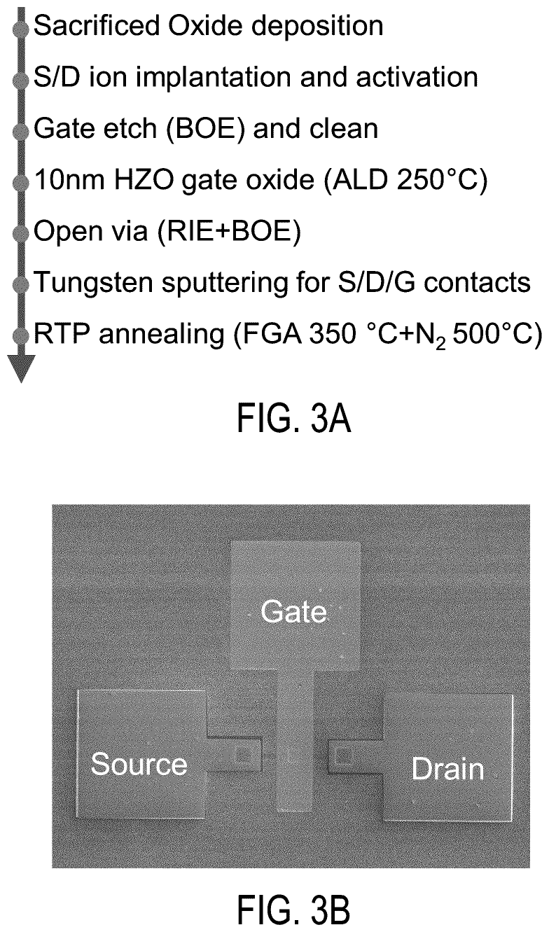

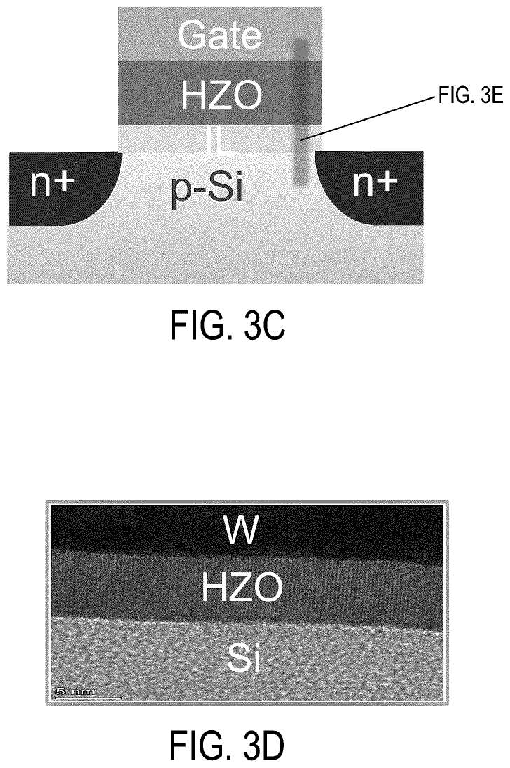

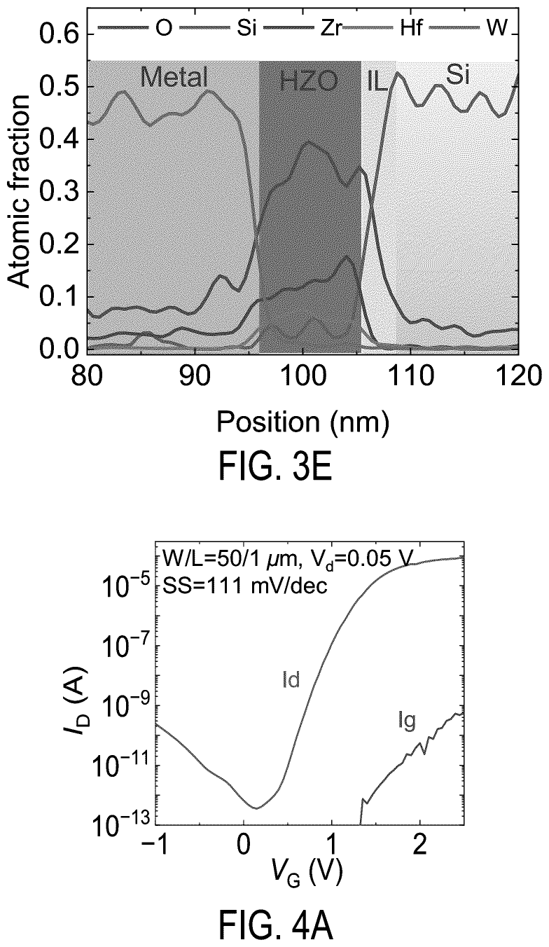

FIGS. 3A-3E illustrate an example process flow and characterization results for a FeFET device that can be used within a NAND string or compute-in-memory array. Each FeFET may include a gate stack incorporating a ferroelectric layer configured to undergo polarization switching, thereby providing a non-volatile polarization state that can modulate a conduction characteristic and an effective gate capacitance of the device. Such devices can serve as individual memory cells capable of storing computational weights and performing localized charge-domain operations when arranged in series strings.

As shown in FIG. 3A, the process may begin with deposition of a sacrificial oxide layer, followed by source/drain (S/D) ion implantation and activation to form doped regions for transistor operation. A gate trench can then be defined using lithography and wet cleaning with buffered-oxide etchant (BOE) to remove surface oxides and prepare the substrate surface.

A ferroelectric oxide layer such as hafnium-zirconium oxide (HfZrO₂ or HZO) can then be deposited. In some examples, this layer may be formed by plasma-enhanced chemical-vapor deposition (PECVD) or by atomic-layer deposition (ALD) at about 250° C. The HZO layer can have a nominal thickness of about 10 nanometers. An additional thin silicon-dioxide or interfacial layer (IL) may be included to improve interface quality and control leakage. The ferroelectric oxide layer can be formed over a silicon or polysilicon channel to provide a ferroelectric switching medium.

Following gate dielectric formation, vias for the source, drain, and gate contacts can be opened by reactive-ion etching (RIE) combined with BOE cleaning. A conductive tungsten (W) film can be deposited by sputtering to form the gate electrode and the metal S/D contacts. The tungsten gate can also serve as the control-gate electrode for both the read cell and the neighboring sense cell when FeFETs are arranged in a NAND string.

After metallization, a rapid-thermal-processing (RTP) sequence may be performed in forming gas (FGA) at approximately 350° C. for about one minute, followed by an anneal in nitrogen (N₂) at approximately 500° C. for about 20 seconds. These anneals can promote ferroelectric crystallization of the HZO layer and stabilize the orthorhombic ferroelectric phase, enabling repeatable polarization switching that defines the stored logic or weight state of the FeFET. The resulting polarization state can alter both the channel conduction and gate capacitance.

FIG. 3B presents a plan-view scanning-electron-microscope (SEM) image of an individual FeFET device, showing the arrangement of the source, drain, and gate regions. When multiple such devices are interconnected through shared bit lines (BLs) and word lines (WLs), the gate region can correspond to a word-line node that functions as a sense node for charge accumulation during compute operations.

FIG. 3C illustrates a schematic cross-section of the FeFET structure, showing a metal gate electrode over the ferroelectric HZO layer, which is disposed on an interfacial dielectric layer (IL) above a p-type silicon substrate with n′ source and drain extensions. The IL can provide interface stability while maintaining strong ferroelectric coupling to the channel. When such FeFETs are vertically or laterally connected, each gate stack can act as a local capacitor whose stored polarization state determines charge transfer to an adjacent word-line node, thereby forming the basis for charge-domain MAC computation.

FIG. 3E presents a transmission-electron-microscope (TEM) cross-section image of the FeFET gate stack corresponding to the schematic in FIG. 3C. Distinct layers of tungsten, HZO, and silicon are visible, confirming sharp interfaces and uniform film thickness. Such structural quality can provide stable ferroelectric polarization retention and reproducible gate-capacitance modulation, which are desirable for accurate sensing at the word-line sense node. Because the process temperatures and materials are compatible with conventional CMOS flows, the FeFET devices can be monolithically integrated with peripheral circuitry within a three-dimensional NAND configuration.

FIG. 3E shows an energy-dispersive X-ray spectroscopy (EDS) elemental-distribution profile measured across the FeFET gate stack to confirm compositional uniformity and material boundaries. The horizontal axis represents position across the gate stack in nanometers (nm), spanning from approximately 80 nm to 120 nm, while the vertical axis represents the atomic fraction of each detected element, ranging from 0 to 0.6.

Distinct traces are observed for oxygen (O), silicon (Si), zirconium (Zr), hafnium (Hf), and tungsten (W), corresponding to the principal constituents of the stacked layers. Moving along the position axis from left to right, a metal region is first identified by the dominance of tungsten and oxygen signals, corresponding to the metal gate electrode. This is followed by a well-defined region characterized by overlapping hafnium and zirconium peaks, indicating the ferroelectric HfZrO₂ (HZO) layer. Beyond the HZO layer, a narrow transition zone is observed with a gradual decrease in Hf and Zr intensity and a rise in Si and O content, corresponding to the interfacial dielectric layer (IL). Finally, a strong Si signal with minimal oxygen content defines the underlying silicon substrate region.

The measured profiles demonstrate sharp elemental transitions at each interface, verifying that the ferroelectric layer, interfacial dielectric, and silicon substrate are compositionally distinct and continuous. The concurrent presence of Hf and Zr within the HZO region confirms formation of the mixed-oxide phase associated with ferroelectric polarization switching, and the clearly separated interfaces indicate a well-controlled deposition and annealing process. Such compositional integrity supports stable polarization retention and reliable gate-capacitance modulation during device operation.

FIGS. 3A-3E demonstrate that the described fabrication and material system can yield a CMOS-compatible FeFET suitable for inclusion in vertically stacked NAND structures. The resulting devices can exhibit polarization-dependent conduction and gate-capacitance modulation, enabling localized charge-domain multiply-accumulate operations.

### Example Electrical Characterization of FeFET Device

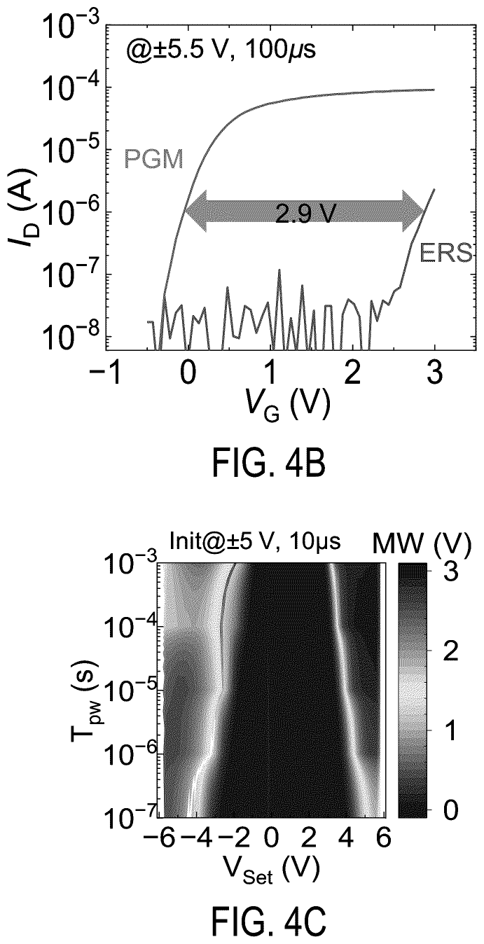

FIGS. 4A-4C illustrate example electrical characterization results of the fabricated FeFET. These measurements demonstrate the transistor's polarization-dependent conduction, memory-window behavior, and switching dynamics under varying pulse conditions. The observed characteristics confirm stable ferroelectric switching and low leakage suitable for charge-domain compute-in-memory operation.

FIG. 4A shows a measured direct-current (DC) drain current (I_{(D)}) versus gate voltage (V_{G}) curve for the FeFET device. The horizontal axis represents gate voltage (V_{G}) ranging from approximately −1 V to +2 V, and the vertical axis represents drain current (I_{D}) in amperes on a logarithmic scale from approximately 10⁻¹³ A to 10⁻⁵ A. The data indicate an I_{ON}/I_{OFF} ratio of about 10⁷ and a subthreshold swing (SS) of approximately 111 mV/decade, confirming steep switching behavior and strong channel control by the ferroelectric gate. A corresponding gate-leakage current (I_{G}) trace is also shown, demonstrating low leakage over the full bias range. These results verify proper ferroelectric-gate operation and minimal leakage through the gate stack, consistent with stable compute functionality.

FIG. 4B presents pulsed I_{D}-V_{G} characteristics measured under two opposite ferroelectric polarization states. The horizontal axis represents gate voltage (V_{G}) from about −1 V to +3 V, and the vertical axis represents drain current (I_{D}) in amperes on a logarithmic scale. During programming (PGM) and erasing (ERS) operations, voltage pulses of approximately +5.5 V for 100 microseconds are applied to the gate. A memory window (MW) of approximately 2.9 V is observed between the two polarization states, indicating distinct threshold-voltage shifts associated with the ferroelectric polarization direction. The wide separation between the PGM and ERS states confirms non-volatile data retention and robust polarization-induced channel modulation in the HZO layer.

FIG. 4C illustrates the switching dynamics of the FeFET device under different pulse amplitudes and pulse widths, demonstrating the evolution of the memory window (MW) as a function of pulse conditions. The horizontal axis represents the set voltage (Vset) applied during programming, ranging from approximately −6 V to +6 V, and the vertical axis represents the pulse width (T_{pw}) in seconds, varying from about 10⁻⁷ s to 10⁻³ s, plotted on a logarithmic scale. The color scale (MW, in volts) indicates the corresponding memory-window magnitude obtained for each voltage-time combination. The data reveal that both the magnitude and polarity of the applied pulse influence the extent of polarization switching, with broader or higher-amplitude pulses producing larger MW values. This behavior demonstrates the device's controllable polarization dynamics and confirms repeatable switching under multiple programming conditions.

### Example Retention and Endurance Characteristics

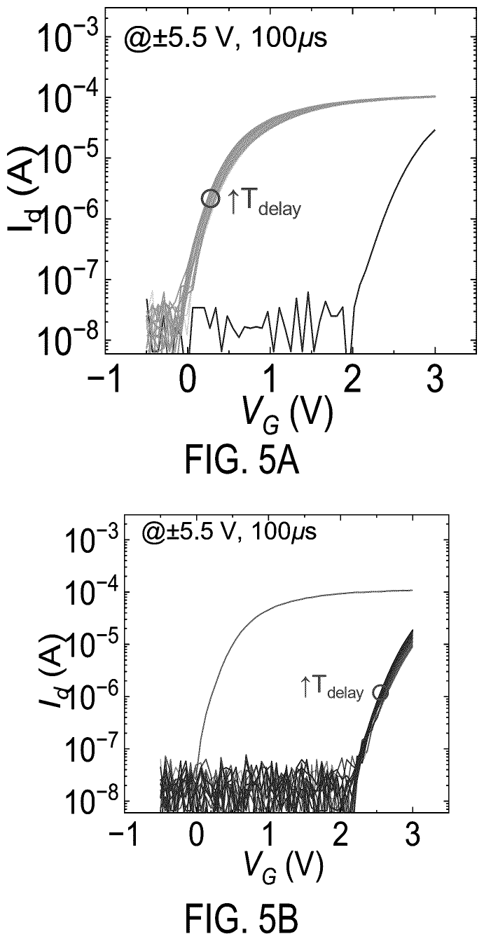

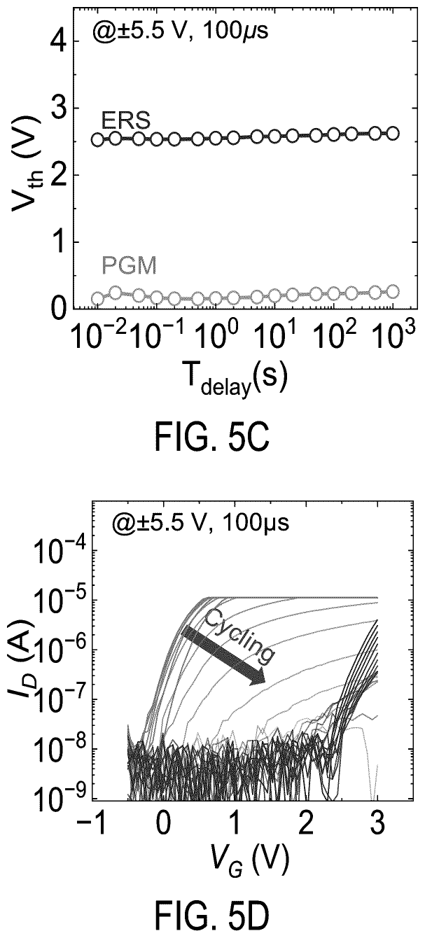

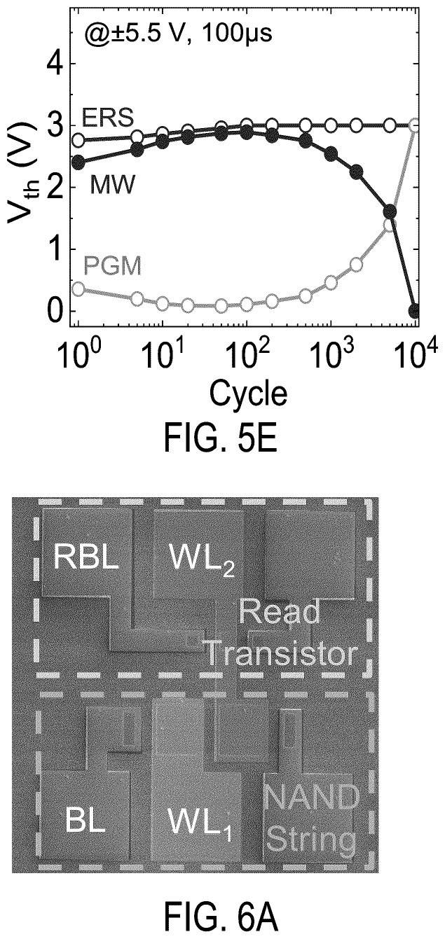

FIGS. 5A-5E illustrate the retention and endurance characteristics of the fabricated FeFET. The measurements demonstrate the stability of the polarization-dependent threshold states and the evolution of the memory window (MW) under repeated cycling.

FIGS. 5A-5C show the retention results for different polarization states, which suggest very stable memory states.

FIG. 5A shows the measured drain-current (Ip)) versus gate-voltage (V_{G}) characteristics of the FeFET under a low-threshold-voltage (LVT) condition. The horizontal axis represents gate voltage (V_{G}) ranging from approximately −1 V to +3 V, and the vertical axis represents drain current (I_{D})) in amperes on a logarithmic scale extending from about 10⁻¹⁰ A to 10⁻³ A. The curves are obtained after applying programming and erasing voltage pulses of approximately ±5.5 V for 100 microseconds. A small shift in threshold voltage (V_{TH}) is observed with increasing delay time (T_{delay}), indicating that the programmed polarization state remains stable with minimal drift.

FIG. 5B presents similar I_{D}-V_{G} characteristics under a high-threshold-voltage (HVT) condition measured over a range of delay times. The axes correspond to those in FIG. 5A. The results show that even after extended delay periods, the high-threshold state exhibits negligible degradation, confirming that both polarization orientations of the ferroelectric gate stack maintain retention over time.

FIG. 5C summarizes the retention behavior by plotting the threshold voltage (V_{TH}) as a function of delay time (T_{delay}). The horizontal axis represents delay time in seconds, spanning approximately 10⁻² s to 10³ s on a logarithmic scale, while the vertical axis represents the extracted threshold voltage (V_{TH}) in volts. Two distinct traces correspond to the programmed (PGM) and erased (ERS) polarization states, which remain well separated across the full time range, demonstrating stable non-volatile retention and minimal charge trapping.

FIGS. 5D and 5E show the write endurance. The memory window totally disappears after 10⁴ cycles' bipolar pulse.

FIG. 5D illustrates the drain-current (I_{D}) versus gate-voltage (V_{G}) characteristics of the FeFET measured during repeated bipolar cycling. The horizontal axis represents V_{G} from approximately −1 V to +3 V, and the vertical axis represents Ip in amperes on a logarithmic scale. The hysteresis loops recorded after multiple cycles show a gradual reduction in memory-window width, reflecting partial depolarization of the ferroelectric layer during extended operation.

FIG. 5E shows the extracted threshold voltages (V_{TH}) and corresponding memory window (MW) as a function of cycle count. The horizontal axis represents the number of program/erase cycles on a logarithmic scale from about 10⁰ to 10⁴, and the vertical axis represents Vₜₕ in volts. The data indicate that the MW remains nearly constant up to approximately 10³ cycles and then gradually decreases, becoming negligible after around 10⁴ cycles.

### Example Validation of Charge-Domain Fe-NAND Compute-in-Memory Design

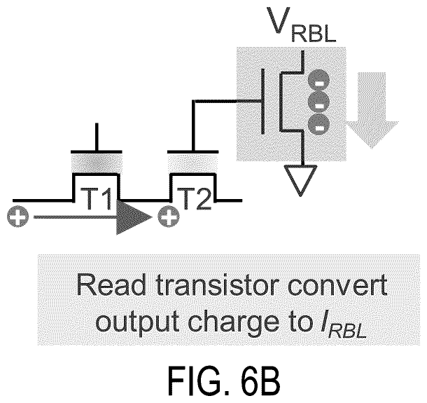

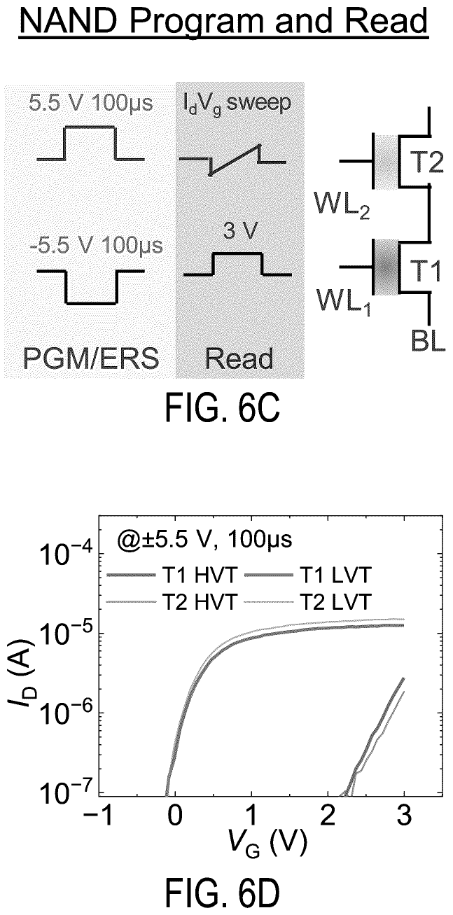

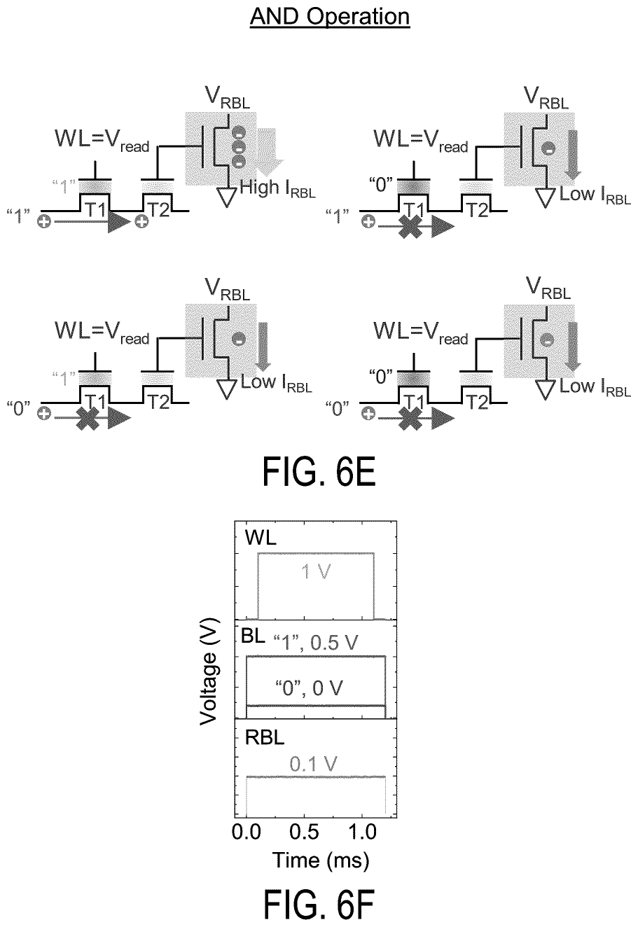

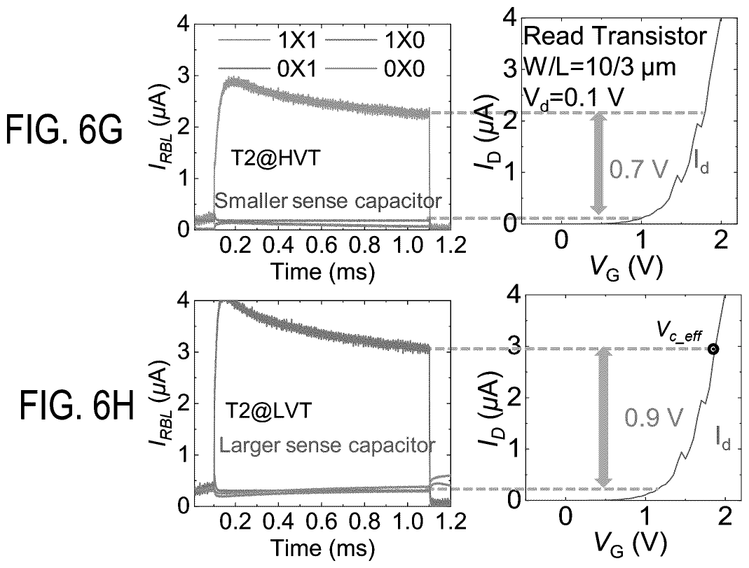

FIGS. 6A-6H illustrate example validation of charge-domain Fe-NAND CIM operation using a fabricated two-FeFET NAND string integrated with a read transistor. The combined structure enables direct monitoring of charge-domain behavior through the transistor current readout, providing experimental verification of the MAC functionality described in the claims.

FIG. 6A shows a top-view scanning-electron-microscope (SEM) image of a fabricated Fe-NAND string that includes two ferroelectric field-effect transistors (FeFETs) and one integrated read transistor. The image highlights the relative placement of the bit line (BL), read bit line (RBL), and word lines (WL₁ and WL₂) defining the Fe-NAND string. The upper portion of the image corresponds to the read transistor region, while the lower portion corresponds to the Fe-NAND string containing transistors T₁ and T₂. The integration of the read transistor enables direct electrical conversion of stored charge into a measurable current, facilitating in-situ readout of charge-domain computation results. The layout demonstrates a compact configuration that allows the FeFET devices and read transistor to share the same interconnect layers and word-line routing, enabling monolithic three-dimensional integration.

FIG. 6B provides a schematic representation of the same Fe-NAND string and readout configuration. Transistors T₁ and T₂ are connected in series between the bit line (BL) and read bit line (RBL). The gate of T₁ is coupled to word line WL₁, and the gate of T₂ is coupled to word line WL₂. Because the charge stored on the gate capacitance of T₂ is difficult to monitor directly, the read transistor is integrated within the same cell to convert the accumulated charge into a drain current I_RBL. This current serves as a measurable analog of the effective charge state, providing a means to verify charge-domain operation within the NAND string. The arrow indicates the direction of charge transfer from T₁ toward T₂ during computation, illustrating how the FeFETs operate as a functional pair for localized MAC or logical AND operations.

FIG. 6C illustrates example programming (PGM) and read configurations used to characterize the Fe-NAND string. The programming (PGM) and erasing (ERS) pulses of approximately ±5.5 V for 100 μs are applied to the word lines to establish distinct ferroelectric polarization states in transistors T₁ and T₂. The read operation is subsequently performed by sweeping the gate voltage (V_{G}) of the selected word line while monitoring the corresponding drain current (I_{D}). The schematic on the right of FIG. 6C indicates the physical arrangement of T₁ and T₂ relative to WL₁, WL₂, and the bit line, showing that read voltages can be applied independently to characterize each device's polarization-dependent transfer characteristics.

FIG. 6D presents measured drain-current (I_{D}) versus gate-voltage (V_{G}) characteristics for both FeFETs (T₁ and T₂) under programmed low-threshold-voltage (LVT) and high-threshold-voltage (HVT) conditions. The horizontal axis represents gate voltage (V_{G}) from approximately −1 V to +3 V, and the vertical axis represents drain current (I_{D}) on a logarithmic scale from 10⁻⁷ A to 10⁻⁴ A. The data demonstrate uniform performance between T₁ and T₂ under identical pulse conditions (±5.5 V, 100 μs), confirming consistent ferroelectric switching characteristics and stable memory-window (MW) behavior across both devices. The distinct separation between LVT and HVT states verifies robust polarization-dependent threshold modulation suitable for charge-domain compute-in-memory operation.

FIG. 6E illustrates the operational principle of a logical AND operation performed within an example two-transistor Fe-NAND cell that includes ferroelectric field-effect transistors (FeFETs) T₁ and T₂, connected in series with a read transistor. During operation, the word line (WL) associated with T₁ is biased at a read voltage (V_{read}), and the output is sensed at the read bit line (RBL) through the read transistor, which converts the charge stored at the gate capacitance of T₂ into a measurable drain current (I_{RBL}). The combination of the applied input signal and the stored ferroelectric polarization state of T₁ determines whether charge transfer to the neighboring sense cell T₂ occurs. When both the input and stored weight are “1,” T₁ is in a low-threshold-voltage (LVT) state that allows the applied input voltage to propagate through the channel, enabling charge coupling to the gate of T₂ and producing a high I_{RBL} at the output. In contrast, when either the input or the weight is “0,” channel conduction is inhibited, preventing charge transfer to the sense node and resulting in a low I_{RBL} output. These four possible combinations of input and weight—(1,1), (0,1), (1,0), and (0,0)—collectively demonstrate that a high read-bit-line current is obtained only when both conditions are true, thereby realizing a logical AND function within the Fe-NAND cell. This confirms that charge-domain computation can be achieved locally between adjacent FeFETs using the intrinsic gate capacitance coupling mechanism.

FIG. 6F illustrates example voltage waveforms corresponding to the logical AND operation described in FIG. 6E. The plots show the applied voltages on the word line (WL), bit line (BL), and read bit line (RBL) as functions of time during a single computation cycle. The upper trace represents the WL signal, which is biased at a read voltage of approximately 1 V for the duration of the operation. The middle trace depicts the BL input signal, which alternates between two discrete states corresponding to binary input levels—“1” represented by 0.5 V and “O” represented by 0 V. The lower trace shows the RBL waveform, where a small sensing voltage of approximately 0.1 V is applied to enable charge transfer monitoring through the read transistor.

During the active phase, when both the BL input and the stored polarization state of transistor T₁ correspond to logical “1” (i.e., when T₁ is in a low-threshold-voltage state), charge is transferred from T₁ to the gate capacitance of T₂, producing a detectable change in the RBL current. In contrast, when either the BL voltage is “0” or the polarization state of T₁ corresponds to a high-threshold-voltage condition, charge transfer does not occur, and the RBL signal remains low. These timing waveforms confirm that the AND operation occurs only under the combined condition of an active input and an LVT polarization state, producing a high read-bit-line current (I_{RBL}) consistent with the charge-domain computation principle.

FIG. 6G illustrates the measured read-bit-line current (I_{RBL}) waveforms corresponding to the AND operation for different combinations of input and weight states, as well as the transfer characteristics of the integrated read transistor used to sense the output charge. The left graph plots I_{RBL} as a function of time during a read cycle for four possible input-weight conditions: (1×1), (1×0), (0×1), and (0×0). When both the input and stored weight are “1,” the FeFET T₁ conducts, and charge is transferred to the neighboring device T₂, resulting in a pronounced current peak at the RBL node. For the other three input-weight combinations, the current remains near zero, indicating minimal or no charge transfer. These results confirm that a high I_{RBL} output occurs only for the (1×1) condition, consistent with the logical AND behavior demonstrated in FIG. 6E.

In this example, the neighboring device T₂ is configured in a high-threshold-voltage (HVT) polarization state, providing a smaller effective gate capacitance that limits the magnitude of the coupled charge and defines the sense-node voltage response. The right graph in FIG. 6G shows the measured drain current (I_{D}) versus gate voltage (V_{G}) characteristic of the read transistor (W/L=10/3 μm, V_{D}=0.1 V). By matching the observed I_{RBL} values from the left plot with this transfer curve, the equivalent sense voltage (V_{c,eff}) corresponding to each AND operation output can be determined. The difference in equivalent charge voltage between the MAC output “1” and “0” states is approximately 0.7 V, demonstrating distinct and well-separated output levels suitable for reliable charge-domain readout and analog-to-digital conversion.

FIG. 6H illustrates the AND-operation readout when the neighboring sense device T₂ is programmed to a low-threshold-voltage (LVT) state, which provides a larger effective gate capacitance than the HVT case of FIG. 6G. The left panel plots the read-bit-line current I(_{RBL}) versus time for the four input-weight combinations (1×1, 1×0, 0×1, 0×0). With T₂@LVT, the (1×1) condition produces a noticeably higher I_{RBL} peak and plateau, reflecting stronger charge coupling into the larger sense capacitor, while the remaining three conditions remain near baseline, confirming AND behavior. The right panel shows the transfer characteristic (I_{D}-V_{G}) of the integrated read transistor used to convert charge to current; by matching the measured I_{RBL} to this curve, the output can be mapped to an equivalent charge voltage V_{c,eff}. Under these conditions, the separation between MAC output “1” and “0” corresponds to approximately 0.9 V, which is larger than the ˜0.7 V obtained when T₂ is in the HVT state. This demonstrates that the ferroelectric state of the sense device modulates the sensing capacitance and thereby the readout margin, with the LVT sense state yielding a larger voltage margin for reliable charge-domain computation.

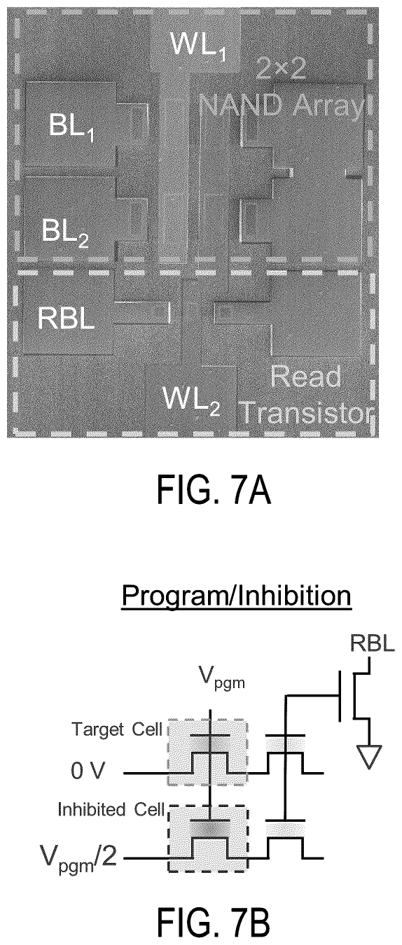

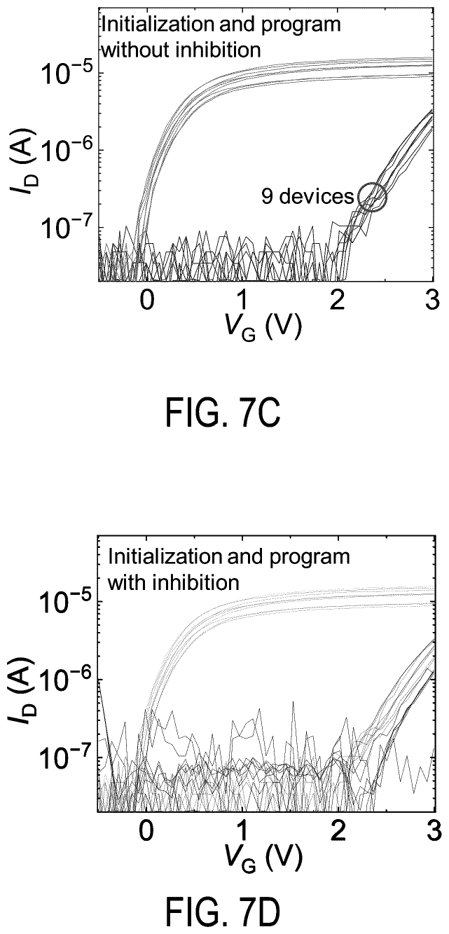

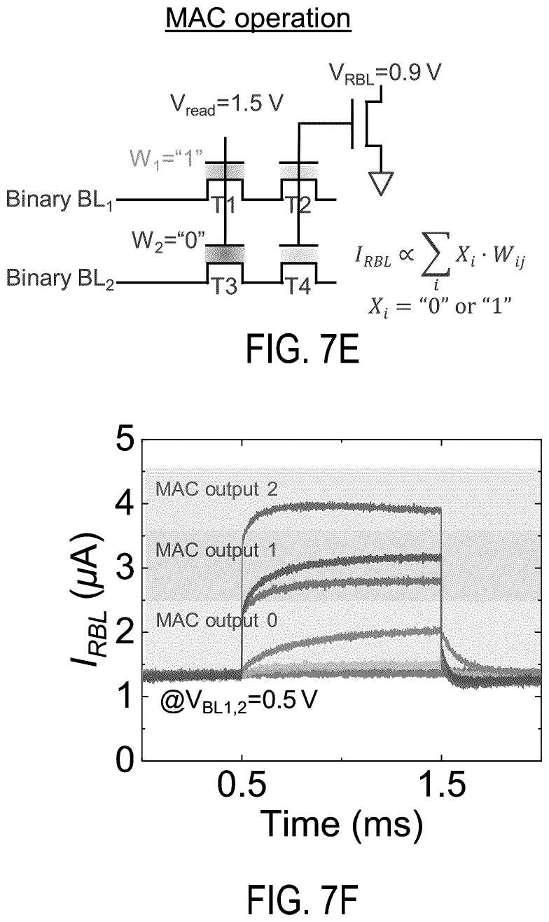

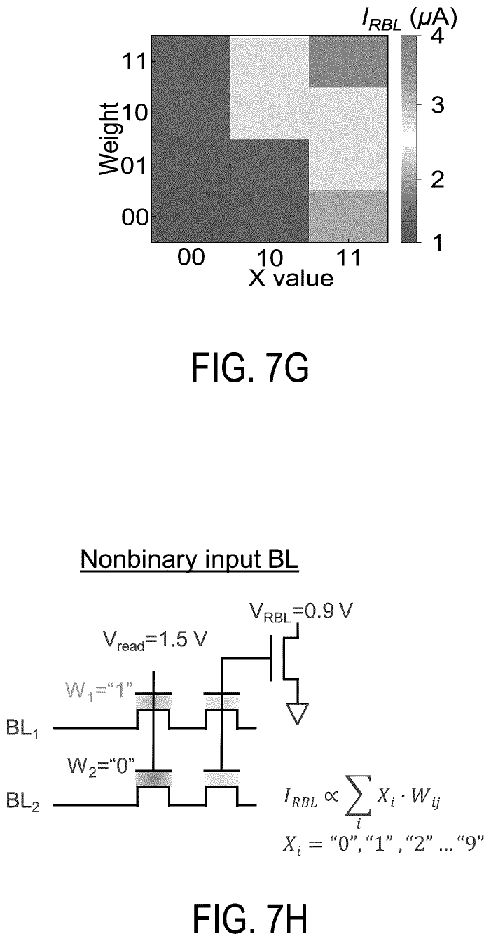

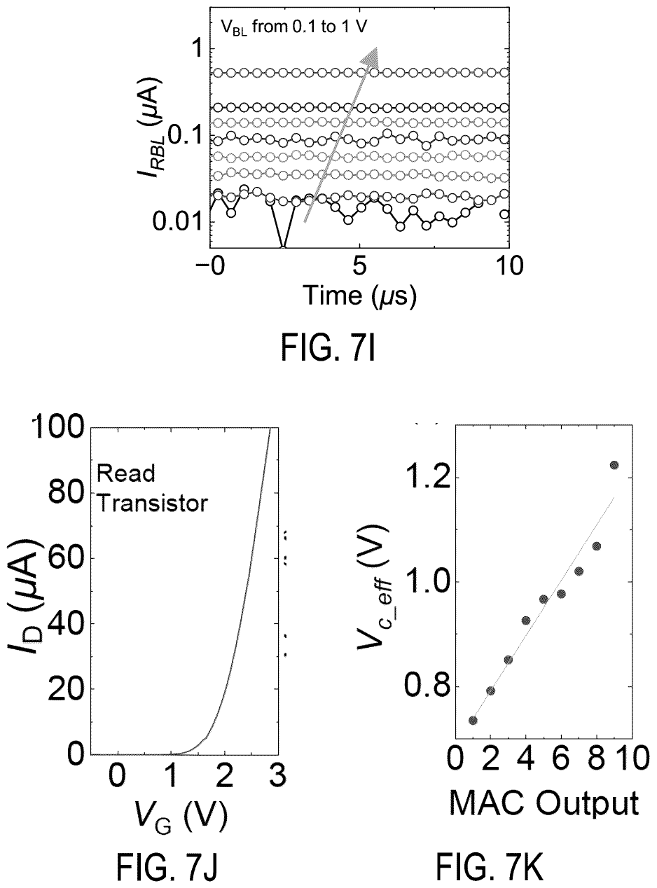

FIGS. 7A-7B illustrate the structure and programming methodology of an integrated 2×2 Fe-NAND array fabricated to validate charge-domain MAC operation.

FIG. 7A presents a top-view scanning-electron-microscope (SEM) image of the fabricated array, which includes four FeFET cells organized in a 2×2 configuration and one integrated read transistor. The layout shows two bit lines (BL₁ and BL₂) arranged vertically, two word lines (WL₁ and WL₂) arranged horizontally, and a shared read bit line (RBL) connected to the read transistor at the array periphery. Each FeFET cell is formed at the intersection of a bit line and a word line, and the read transistor provides current-sensing capability for the charge-domain output. This compact configuration enables individual device addressing and localized charge-domain sensing while maintaining structural compatibility with conventional NAND architecture. The fabricated array allows for verification of both binary and nonbinary input computation, serving as an experimental platform for demonstrating charge-domain MAC functionality.

FIG. 7B illustrates the programming and inhibition scheme used to selectively write polarization states to individual FeFET cells within the array. Unlike single-cell programming, where a full program voltage (V_{pgm}) is applied across the target device, array-level operation requires an inhibition technique to prevent unintended switching of neighboring cells. During programming, the drain of the target cell is held at 0 V, while the drain of an inhibited cell is biased at V_{pgm}/2. This configuration reduces the effective gate-to-drain voltage across the inhibited cell to half the nominal programming voltage, thereby suppressing polarization switching in non-targeted devices. As a result, only the target FeFET undergoes polarization reversal, ensuring selective programming and maintaining the integrity of stored weights in the surrounding cells.

This inhibition scheme allows independent writing of each FeFET within the 2×2 array without cross-disturbance, enabling precise initialization of weight states prior to MAC computation. After all FeFETs are programmed into desired polarization configurations, the array can be used for charge-domain inference testing, where word lines are biased at a read voltage (V_{read}) and bit lines are driven with analog or digital input levels. This structure and method collectively provide a robust foundation for validating localized charge-domain computation in a multi-cell NAND array.

FIG. 7C shows the measured drain-current (I_{D}) versus gate-voltage (V_{G}) characteristics for multiple FeFET devices after initialization and programming without inhibition. The horizontal axis represents V_{G} ranging from approximately 0 V to 3 V, while the vertical axis represents I_{D} in amperes on a logarithmic scale from 10⁻⁷ A to 10⁻⁵ A. The curves show data from nine FeFET devices within the array. When programmed without inhibition, all cells exposed to the full programming voltage (V_{pgm}) exhibit significant threshold-voltage shifts, indicating that both the target and neighboring cells undergo polarization switching. The overlapping transfer curves demonstrate that the absence of an inhibition bias results in unintentional programming of adjacent cells, preventing selective state control and leading to loss of individual cell addressability.

FIG. 7D presents corresponding I_{D}-V_{G} characteristics obtained from the same array when programming is performed with inhibition applied according to the biasing scheme described in FIG. 7B. In this configuration, the drain of the target cell is held at 0 V, while the drains of neighboring (inhibited) cells are biased at V_{pgm}/2, reducing the effective programming field. The results show that only the target cells experience a clear threshold-voltage shift following programming, while the inhibited cells retain their initial transfer characteristics with negligible change. The distinct separation between programmed and inhibited states confirms that the inhibition method effectively suppresses undesired polarization switching, enabling precise and independent weight programming in the 2×2 Fe-NAND array.

FIG. 7E illustrates the operational principle of the MAC function performed within the fabricated 2×2 Fe-NAND array. The schematic shows four FeFETs, labeled T₁-T₄, arranged in two parallel NAND strings corresponding to bit lines BL₁ and BL₂, and two word lines WL₁ and WL₂ that store the ferroelectric weight states. In the depicted example, the FeFET connected to WL₁ is programmed with a low-threshold-voltage (LVT) polarization state representing a stored weight W₁=“1”, while the FeFET connected to WL₂ is in a high-threshold-voltage (HVT) state representing W₂=“0”. The word line under test is biased at a read voltage V_{read}=1.5 V, and the read bit line (RBL) is held at approximately 0.9 V for current sensing.

During operation, binary or analog input signals are applied to the bit lines, where each input Xᵢ corresponds to a voltage representing logical “0” or “1.” The charge transferred from each active FeFET channel to the corresponding sense node is proportional to the product of the stored weight and the applied input. The read-bit-line current therefore follows a relationship of the form:

$${I}_{RBL} ∝ {\sum }_{i} ( {W}_{ij} \times {X}_{i} ) \qquad ( Equation 2 )$$

where Wᵢⱼ denotes the stored polarization state (weight) and Xᵢ represents the applied input signal. The current sensed at RBL thus reflects the weighted sum of the active inputs along the bit lines, achieving charge-domain MAC functionality within the Fe-NAND array.

FIG. 7F presents the measured read-bit-line current (I_{RBL}) as a function of time for different MAC outputs obtained from the array. The horizontal axis represents time in milliseconds, and the vertical axis represents I_{RBL} in microamperes (μA). Three distinct output levels—labeled MAC output 0, MAC output 1, and MAC output 2—are observed when combinations of input and weight states are applied across the two bit lines. For the measurement shown, both BL₁ and BL₂ are biased at V_{BL1,2}=0.5 V, corresponding to active input conditions. The resulting I_{RBL} traces exhibit stepwise increments proportional to the number of active (1×1) input-weight pairs, demonstrating linear accumulation of charge in the readout node. The data confirm that the 2×2 Fe-NAND array successfully performs charge-domain MAC operations, with distinct current levels corresponding to different dot-product results, validating the feasibility of the proposed in-memory computing architecture.

FIG. 7G illustrates the measured read-bit-line current (I_{RBL}) results for different combinations of binary input (X) and binary weight (W) states in the 2×2 Fe-NAND array. The heatmap shows I_{RBL} in microamperes (μA) as a function of the applied input and programmed weight conditions, where the horizontal axis represents the input combinations (X=00, 10, 01, 11) and the vertical axis represents the stored weight combinations (W=00, 01, 10, 11). The color scale corresponds to the magnitude of the measured current, increasing from blue (low current) to red (high current). The data demonstrate a clear stepwise increase in I_{RBL} with the number of active (1×1) input-weight pairs. The highest output current is observed for the fully active condition (X=11, W=11), while combinations involving any inactive input or weight produce proportionally lower current levels. These results confirm the correct MAC functionality of the charge-domain Fe-NAND array and verify that the read-bit-line current scales with the total number of activated cells, reflecting accurate summation of the input-weight products.

FIG. 7H illustrates an extension of the same Fe-NAND array operation for nonbinary input computation. In this configuration, the architecture and device states remain the same as in FIG. 7E, but the bit-line inputs (BL₁ and BL₂) are driven with analog voltages representing multiple discrete input levels rather than binary “0” or “1.” The schematic shows that each bit line can receive an input voltage (V_{BL}) ranging from 0.1 V to 1.0 V, corresponding to input states Xᵢ=“0”, “1”, “2”, . . . , “9.” The word lines (WL₁, WL₂) store ferroelectric polarization states representing weights W₁ and W₂, while the read bit line (RBL) and read transistor sense the accumulated charge response. The resulting relationship, I_{RBL}∝Σᵢ (Wᵢⱼ×Xᵢ), remains valid, but the magnitude of the current now scales continuously with the applied analog input voltage. Experimental results show that as V_{BL} increases from 0.1 V to 1.0 V, I_{RBL} increases proportionally, demonstrating a linear correlation between the effective charge voltage (V_{c,eff}) and the MAC output. This confirms that the Fe-NAND charge-domain compute-in-memory architecture supports multi-level or analog input operation, enabling higher computational precision beyond binary logic.

FIG. 7I shows the measured read-bit-line current (I_{RBL}) waveforms obtained during nonbinary input operation of the 2×2 Fe-NAND array. The horizontal axis represents time in microseconds (μs), while the vertical axis represents I_{RBL} in microamperes (μA) plotted on a logarithmic scale. The series of traces correspond to bit-line voltages (V_{BL}) incremented from 0.1 V to 1.0 V, representing multi-level input values from X=1 through X=10. As the applied V_{BL} increases, the amplitude of the measured I_{RBL} also increases proportionally, indicating that larger input voltages inject more charge into the neighboring sense node. The distinct and monotonic current levels across the input range confirm the capability of the charge-domain Fe-NAND array to perform analog-weighted accumulation, with precise control over output magnitude according to the input level.

FIG. 7J presents the transfer characteristic (I_{D}-V_{G}) of the integrated read transistor used to convert the sensed charge from the Fe-NAND array into measurable current. The horizontal axis represents gate voltage (V_{G}) ranging from 0 V to 3 V, while the vertical axis represents drain current (I_{D}) in microamperes. The curve shows a steep, exponential increase in current as V_{G} exceeds the threshold, confirming strong gate control and low leakage. This characteristic is used to calibrate and translate the measured I_{RBL} from the array into the corresponding effective charge voltage (V_{c,eff}), providing a quantitative relationship between charge accumulation and equivalent voltage output.

FIG. 7K shows the extracted Veer as a function of the MAC output index obtained from the nonbinary computation tests. The horizontal axis represents the MAC output level, ranging from 0 to 10, and the vertical axis represents the corresponding V_{c,eff} in volts. The data points exhibit a near-linear correlation, demonstrating that the effective charge voltage increases proportionally with the number or magnitude of active input-weight pairs. This linearity confirms accurate analog summation in the charge domain and validates that the Fe-NAND architecture supports multi-level or continuous-valued input computation, enabling high-precision in-memory analog processing suitable for neuromorphic and machine-learning applications.

### Simulation and System Benchmarking

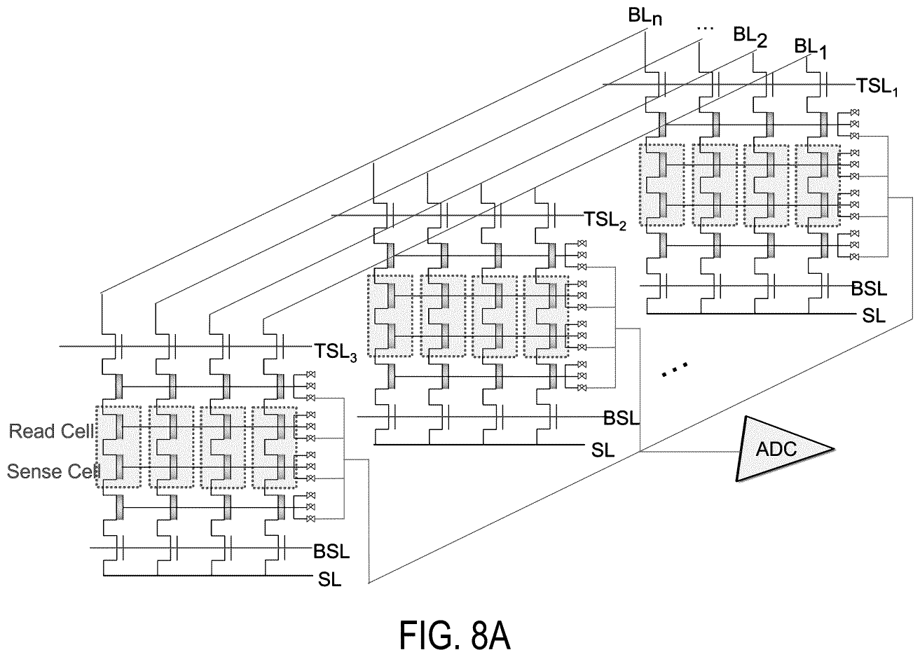

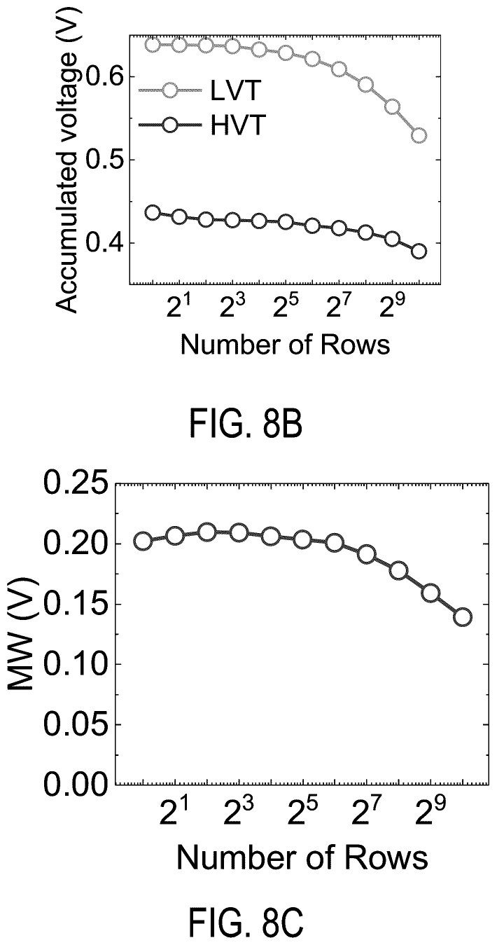

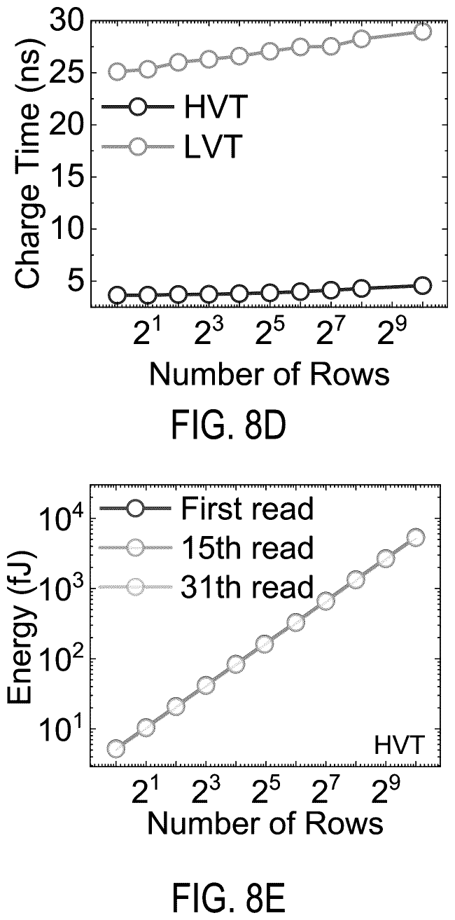

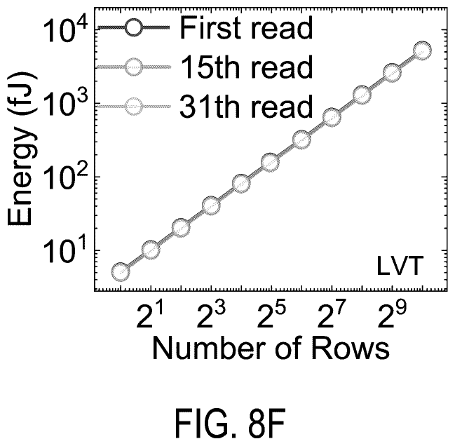

FIGS. 8A-8F illustrate simulated characteristics of a charge-domain CIM architecture based on FeFET NAND strings, evaluated using a 28 nm process design kit (PDK). In these simulations, high-threshold-voltage (HVT) and low-threshold-voltage (LVT) transistors from the PDK are used to emulate FeFETs in their respective polarization states. Each NAND string consists of 32 transistors connected in series, and charge transfer and computation are simulated in two sequential steps. In the first step, the gates of the top select line (TSL) and the read cell are held high (ON), and the gate of the sense cell is pre-charged to a specific voltage. In the second step, the TSL is turned OFF while a read voltage is applied to the read cell. This initiates charge transfer between the read and sense cells, and the resulting charge accumulation at the sense cell represents the computed result. The transfer time is directly influenced by the read transistor characteristics, as charge moves through the resistive path formed between the source and drain nodes during computation.

FIG. 8A shows the simulated architecture of the FeFET NAND-based CIM array. Each column represents a NAND string with alternating read and sense cells connected by word lines (WL₁-WLₙ) and bit lines (BL₁-BLₙ). Top select lines (TSL₁-TSLₙ) and bottom select lines (BSL) connect the strings to shared source lines (SL) and read circuits. The architecture includes an analog-to-digital converter (ADC) for quantizing the sensed charge-domain output voltage. The simulation replicates computation across multiple strings and rows, allowing evaluation of accumulated charge, latency, and energy scaling with array size.

FIG. 8B shows the simulated accumulated voltage at the sense node for cases in which all FeFETs are in either the HVT or LVT state, plotted against the number of rows in the array. The horizontal axis represents the number of rows (from 2¹ to 2⁹), and the vertical axis represents accumulated voltage in volts. The LVT configuration exhibits a higher accumulated voltage due to greater charge transfer through low-resistance paths, while the HVT configuration produces lower voltage levels. A gradual voltage degradation is observed for both states as the array size increases, which is attributed to the parasitic capacitance between the gate and drain of the sense cells. As the array scales, this parasitic capacitance adds in parallel, reducing the total charge-coupling efficiency.

FIG. 8C illustrates the memory window (MW) between the accumulated charges for the LVT and HVT configurations as a function of array size. The MW, defined as the voltage difference between the LVT and HVT accumulated voltages, initially remains stable but gradually decreases as the array size increases. This degradation is caused by accumulated parasitic effects, which reduce the differential signal margin. The MW determines the reference voltages required for the analog-to-digital conversion of charge-domain outputs in large-scale CIM arrays.

FIG. 8D presents the simulated latency (charge time) required for charge transfer in both HVT and LVT cases as the array size increases. The horizontal axis represents the number of rows, and the vertical axis represents charge time in nanoseconds (ns). The LVT devices exhibit the worst-case latency, while the HVT devices represent the best-case latency. This behavior arises because the ON-state conduction in LVT devices allows slower charge equilibration through resistive paths, whereas HVT devices, being mostly OFF, transfer less charge more quickly.

FIG. 8E shows the compute energy consumption for the HVT configuration, and FIG. 8F shows the same for the LVT configuration, each plotted as a function of array size. The horizontal axis represents the number of rows, and the vertical axis represents energy in femtojoules (fJ). Three traces are plotted for the first, fifteenth, and thirty-first read operations to evaluate read stability over repeated cycles. In both cases, the compute energy scales approximately linearly with the number of rows, reflecting the cumulative energy required to charge additional sense nodes as the array grows. The overall energy consumption remains in the femtojoule range, confirming the high energy efficiency of charge-domain computation.

These simulation results collectively demonstrate that the FeFET NAND charge-domain architecture supports scalable and energy-efficient computation. The analysis highlights trade-offs between voltage margin, latency, and energy with array size, providing design guidance for optimizing large-scale compute-in-memory implementations.

### CONCLUSION

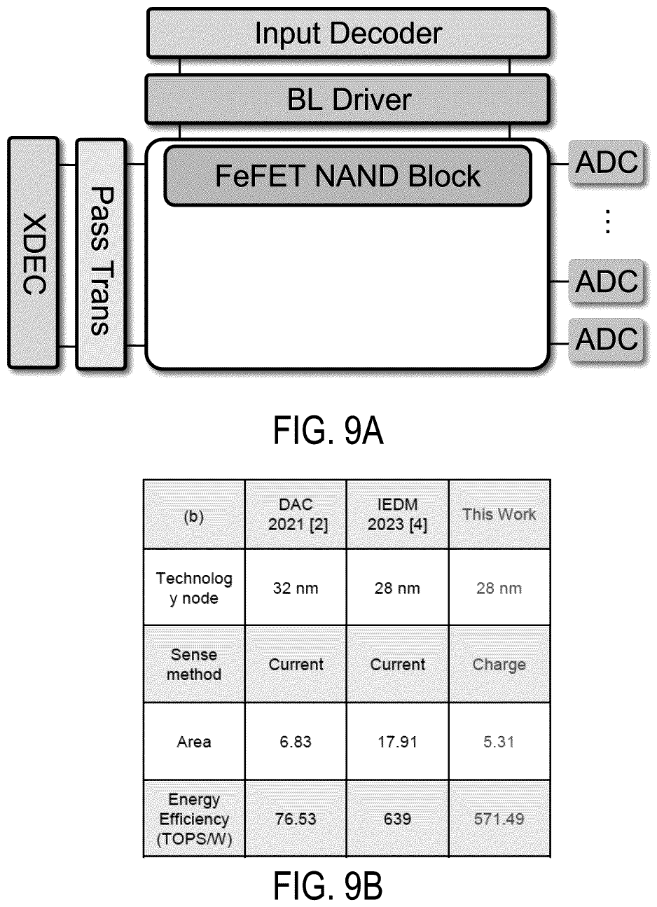

FIGS. 9A-9B illustrate the subarray architecture and performance comparison of a Fe-NAND charge-domain CIM system in accordance with some aspects of the inventive concepts with previously reported NAND-based CIM implementations.

FIG. 9A presents a schematic diagram of the Fe-NAND subarray design, showing the main circuit components that enable charge-domain computation. The subarray includes an input decoder and bit-line (BL) driver that apply voltage signals representing input data to selected bit lines. The FeFET NAND block forms the computational core, including NAND strings that integrate ferroelectric field-effect transistors (FeFETs) for non-volatile storage and charge-domain MAC operation. Each NAND string includes stacked FeFETs acting as read and sense cells that perform localized charge accumulation during computation. Peripheral circuits include pass transistors and an X-decoder (XDEC) for row and column addressing, enabling selective activation of word lines and bit lines during programming, reading, and inference. The accumulated charge from the FeFET NAND block is sensed through analog-to-digital converters (ADCs), which are coupled at the array periphery. Multiple ADCs can operate in parallel to digitize the charge-domain outputs from different NAND strings, allowing scalable and high-throughput operation. This modular design supports integration with standard CMOS logic and peripheral circuitry for efficient analog in-memory processing.

FIG. 9B provides a quantitative comparison between the disclosed Fe-NAND charge-domain CIM system and prior NAND-based CIM works reported in DAC 2021 [2] and IEDM 2023 [4]. The comparison table includes four key metrics: technology node, sensing method, area, and energy efficiency. The DAC 2021 design uses a 32 nm process and current-domain sensing, achieving an energy efficiency of 76.53 TOPS/W with an area of 6.83 (normalized units). The IEDM 2023 implementation uses a 28 nm process, also based on current-domain sensing, with an energy efficiency of 639 TOPS/W and a larger area of 17.91. In contrast, the present work, implemented in a 28 nm process node, employs a charge-domain sensing scheme that eliminates the need for cumulative current summation and improves scalability. The proposed design achieves a compact area of 5.31 and a high energy efficiency of 571.49 TOPS/W, demonstrating competitive or superior performance to prior NAND-based CIM architectures.

These results highlight that the transition from current-domain to charge-domain computation significantly improves energy efficiency while maintaining compatibility with standard NAND fabrication processes. The compact area and scalable architecture shown in FIG. 9A, together with the performance advantages summarized in FIG. 9B, confirm the viability of the proposed Fe-NAND charge-domain CIM system for future high-density, low-power AI and machine-learning hardware accelerators.

In accordance with some embodiments, a charge-domain CIM architecture is provided that employs a NAND-type array of ferroelectric field-effect transistors (FeFETs). The disclosed architecture can exhibit improved resilience to device-to-device variation relative to conventional current-domain CIM approaches, thereby enhancing inference accuracy and reducing power consumption. In some implementations, the architecture is further compatible with multi-level or nonbinary input operations. The functionality of the charge-domain FeFET NAND structure has been experimentally verified using a fabricated array, confirming the feasibility of the disclosed design for energy-efficient and variation-tolerant in-memory computing applications.

### Terminology

Computer programs typically comprise one or more instructions set at various times in various memory devices of a computing device, which, when read and executed by at least one processor, will cause a computing device to execute functions involving the disclosed techniques. In some embodiments, a carrier containing the aforementioned computer program product is provided. The carrier is one of an electronic signal, an optical signal, a radio signal, or a non-transitory computer-readable storage medium.

Any or all of the features and functions described above can be combined with each other, except to the extent it may be otherwise stated above or to the extent that any such embodiments may be incompatible by virtue of their function or structure, as will be apparent to persons of ordinary skill in the art. Unless contrary to physical possibility, it is envisioned that (i) the methods/steps described herein may be performed in any sequence and/or in any combination, and (ii) the components of respective embodiments may be combined in any manner.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims, and other equivalent features and acts are intended to be within the scope of the claims.

Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Unless the context clearly requires otherwise, throughout the description and the claims, the words “comprise,” “comprising,” and the like are to be construed in an inclusive sense, as opposed to an exclusive or exhaustive sense, e.g., in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words using the singular or plural number may also include the plural or singular number respectively. The word “or” in reference to a list of two or more items, covers all of the following interpretations of the word: any one of the items in the list, all of the items in the list, and any combination of the items in the list. Likewise the term “and/or” in reference to a list of two or more items, covers all of the following interpretations of the word: any one of the items in the list, all of the items in the list, and any combination of the items in the list.

Conjunctive language such as the phrase “at least one of X, Y and Z,” unless specifically stated otherwise, is otherwise understood with the context as used in general to convey that an item, term, etc. may be either X, Y or Z, or any combination thereof. Thus, such conjunctive language is not generally intended to imply that certain embodiments require at least one of X, at least one of Y and at least one of Z to each be present. Further, use of the phrase “at least one of X, Y or Z” as used in general is to convey that an item, term, etc. may be either X, Y or Z, or any combination thereof.

In some embodiments, certain operations, acts, events, or functions of any of the algorithms described herein can be performed in a different sequence, can be added, merged, or left out altogether (e.g., not all are necessary for the practice of the algorithms). In certain embodiments, operations, acts, functions, or events can be performed concurrently, e.g., through multi-threaded processing, interrupt processing, or multiple processors or processor cores or on other parallel architectures, rather than sequentially.

Systems and modules described herein may comprise software, firmware, hardware, or any combination(s) of software, firmware, or hardware suitable for the purposes described. Software and other modules may reside and execute on servers, workstations, personal computers, computerized tablets, PDAs, and other computing devices suitable for the purposes described herein. Software and other modules may be accessible via local computer memory, via a network, via a browser, or via other means suitable for the purposes described herein. Data structures described herein may comprise computer files, variables, programming arrays, programming structures, or any electronic information storage schemes or methods, or any combinations thereof, suitable for the purposes described herein. User interface elements described herein may comprise elements from graphical user interfaces, interactive voice response, command line interfaces, and other suitable interfaces.

Embodiments are also described above with reference to flow chart illustrations and/or block diagrams of methods, apparatus (systems) and computer program products. Each block of the flow chart illustrations and/or block diagrams, and combinations of blocks in the flow chart illustrations and/or block diagrams, may be implemented by computer program instructions. Such instructions may be provided to a processor of a general purpose computer, special purpose computer, specially-equipped computer (e.g., comprising a high-performance database server, a graphics subsystem, etc.) or other programmable data processing apparatus to produce a machine, such that the instructions, which execute via the processor(s) of the computer or other programmable data processing apparatus, create means for implementing the acts specified in the flow chart and/or block diagram block or blocks. These computer program instructions may also be stored in a non-transitory computer-readable memory that can direct a computer or other programmable data processing apparatus to operate in a particular manner, such that the instructions stored in the computer-readable memory produce an article of manufacture including instruction means which implement the acts specified in the flow chart and/or block diagram block or blocks. The computer program instructions may also be loaded to a computing device or other programmable data processing apparatus to cause operations to be performed on the computing device or other programmable apparatus to produce a computer implemented process such that the instructions which execute on the computing device or other programmable apparatus provide steps for implementing the acts specified in the flow chart and/or block diagram block or blocks.

Any patents and applications and other references noted above, including any that may be listed in accompanying filing papers, are incorporated herein by reference. Aspects of the invention can be modified, if necessary, to employ the systems, functions, and concepts of the various references described above to provide yet further implementations of the invention. These and other changes can be made to the invention in light of the above Detailed Description. While the above description describes certain examples of the invention, and describes the best mode contemplated, no matter how detailed the above appears in text, the invention can be practiced in many ways. Details of the system may vary considerably in its specific implementation, while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed in the specification, unless the above Detailed Description section explicitly defines such terms. Accordingly, the actual scope of the invention encompasses not only the disclosed examples, but also all equivalent ways of practicing or implementing the invention under the claims.

To reduce the number of claims, certain aspects of the invention are presented below in certain claim forms, but the applicant contemplates other aspects of the invention in any number of claim forms. Any claims intended to be treated under 35 U.S.C. § 112 (f) will begin with the words “means for,” but use of the term “for” in any other context is not intended to invoke treatment under 35 U.S.C. § 112 (f). Accordingly, the applicant reserves the right to pursue additional claims after filing this application, in either this application or in a continuing application.

What is claimed is:

1. A compute-in-memory device comprising:
a plurality of memory cells arranged in a string and coupled to a plurality of word lines and a plurality of bit lines;
each memory cell being a ferroelectric field-effect transistor (FeFET) configured to store a weight as a non-volatile polarization state produced by polarization switching of a ferroelectric layer that alters a conduction characteristic of the memory cell and modulates a gate capacitance of the memory cell;
a read cell selected from the plurality of memory cells and configured to receive an input signal applied on one of the plurality of bit lines;
a neighboring memory cell adjacent to the read cell and having a gate capacitance that forms a sense node, the sense node comprising a word line of the neighboring memory cell;
a control circuit configured to bias the read cell and the neighboring memory cell such that application of the input signal to the read cell conditionally transfers charge to the gate capacitance of the neighboring memory cell based on a combination of the input signal and the polarization-dependent conduction characteristic of the read cell; and
a readout circuit configured to sense an electrical quantity at the sense node to obtain a compute result corresponding to a multiply-accumulate operation performed in a charge domain.

2. The device of claim 1, wherein the multiply-accumulate operation is performed using a localized computation that does not require summing current across multiple memory cells in the string.

3. The compute-in-memory device of claim 1, wherein the polarization switching of the ferroelectric layer establishes a polarization state that determines a gate capacitance of the memory cell, and the conditional transfer of charge is based on the polarization state.

4. The compute-in-memory device of claim 1, wherein the readout circuit is configured to sense a voltage on the word line of the neighboring memory cell as the electrical quantity.

5. The compute-in-memory device of claim 1, wherein the compute result is determined solely by the gate capacitance of the neighboring memory cell, and conduction characteristics of memory cells in the string other than the read cell and the neighboring memory cell do not contribute to the compute result.

6. The compute-in-memory device of claim 1, wherein the control circuit is further configured to sequentially select different pairs of adjacent memory cells as the read cell and the neighboring memory cell to perform successive multiply-accumulate operations along the string.

7. The compute-in-memory device of claim 1, wherein the input signal comprises a multi-level or analog voltage, and an amount of charge transferred to the gate capacitance of the neighboring memory cell is proportional to a magnitude of the input voltage.

8. The compute-in-memory device of claim 1, wherein different polarization states of the ferroelectric layer produce distinct gate capacitance values that form a memory window used by the readout circuit to differentiate multiply-accumulate output levels.

9. The compute-in-memory device of claim 1, further comprising a read transistor coupled to the neighboring memory cell and configured to convert charge accumulated at the sense node into a measurable current or voltage for the readout circuit.

10. The compute-in-memory device of claim 1, wherein the ferroelectric field-effect transistor is fabricated using a CMOS-compatible process to enable monolithic integration of the plurality of memory cells with peripheral circuitry.

11. The compute-in-memory device of claim 1, wherein the plurality of memory cells are vertically stacked in a three-dimensional NAND structure.

12. The compute-in-memory device of claim 1, wherein the control circuit is configured to accumulate charge on the gate capacitance of the neighboring memory cell over multiple input cycles to generate a multiply-accumulate result.

13. The compute-in-memory device of claim 1, further comprising a programming circuit configured to apply a program voltage to a selected one of the plurality of memory cells and a reduced voltage to non-selected memory cells to maintain polarization states of the non-selected memory cells during programming.

14. The compute-in-memory device of claim 1, wherein the control circuit is configured to turn on memory cells on one side of the read cell to propagate the input signal to the read cell and to turn off memory cells on an opposite side of the neighboring memory cell to isolate the sense node during the conditional transfer of charge.

15. A method of performing compute-in-memory operations, the method comprising:
storing a weight in a memory cell of a string of memory cells, the memory cell being a ferroelectric field-effect transistor (FeFET) and the weight being stored as a non-volatile polarization state produced by polarization switching of a ferroelectric layer that alters a conduction characteristic of the memory cell and modulates a gate capacitance of the memory cell;
applying an input signal to a read cell of the string through a bit line;
biasing a neighboring memory cell adjacent to the read cell, the neighboring memory cell having a gate capacitance that forms a sense node, the sense node comprising a word line of the neighboring memory cell;
conditionally transferring charge to the gate capacitance of the neighboring memory cell based on a combination of the input signal and the polarization-dependent conduction characteristic of the read cell, while controlling conduction states of other memory cells in the string to propagate the input signal toward the read cell and isolate the sense node; and
sensing an electrical quantity at the sense node to obtain a compute result without summing current through an entire string of memory cells, the compute result corresponding to a multiply-accumulate operation performed in a charge domain using the gate capacitance of the neighboring memory cell.

16. The method of claim 15, wherein sensing the electrical quantity at the sense node comprises measuring a voltage on the word line of the neighboring memory cell generated by charge accumulated on a gate capacitance of the neighboring memory cell due to polarization switching of the ferroelectric layer.

17. The method of claim 15, further comprising turning on memory cells on a first side of the read cell to propagate the input signal to the read cell and turning off memory cells on an opposite side of the neighboring memory cell to isolate the sense node during the conditional transfer of charge.

18. The method of claim 15, further comprising sequentially selecting different pairs of adjacent memory cells as the read cell and the neighboring memory cell to perform successive multiply-accumulate operations along the string.

19. A system comprising:
a compute-in-memory array including a plurality of memory cells arranged in a string and coupled to a plurality of word lines and a plurality of bit lines, each memory cell being a ferroelectric field-effect transistor (FeFET) configured to store a weight as a non-volatile polarization state produced by polarization switching of a ferroelectric layer that alters a conduction characteristic of the memory cell and modulates a gate capacitance of the memory cell;
a control circuit configured to:
select a read cell from the plurality of memory cells and apply an input signal to the read cell on one of the plurality of bit lines;
bias a neighboring memory cell adjacent to the read cell, the neighboring memory cell having a gate capacitance that forms a sense node, the sense node comprising a word line of the neighboring memory cell; and
cause conditional transfer of charge to the gate capacitance of the neighboring memory cell based on a combination of the input signal and the polarization-dependent conduction characteristic of the read cell; and
a readout circuit configured to sense an electrical quantity at the sense node to obtain a compute result without summing current through an entire string of memory cells, the compute result corresponding to a multiply-accumulate operation performed in a charge domain using the gate capacitance of the neighboring memory cell.

20. The system of claim 19, wherein the control circuit is further configured to turn on one or more memory cells on a first side of the read cell to propagate the input signal to the read cell and to turn off one or more memory cells on an opposite side of the neighboring memory cell to isolate the sense node during the conditional transfer of charge.
